(19) United States
(12) Patent Application Publication
(10) Pub. No.: US 2010/0225591 A1
(43) Pub. Date: Sep. 9, 2010

(54) HIGHLY COMPACT KEYBOARDS

(76) Inventor: Scott Macfarlane, Manlius, NY (US)

Correspondence Address: MARJAMA MULDOON BLASIAK & SULLIVAN LLP, 250 SOUTH CLINTON STREET, SUITE 300, SYRACUSE, NY, 13202, US

(21) Appl. No.: 12/723,344

(22) Filed: Mar. 12, 2010

Related U.S. Application Data
(63) Continuation-in-part of application No. PCT/US08/76201, filed on Sep. 12, 2008.
(60) Provisional application No. 60/971,613, filed on Sep. 12, 2007.

(51) Int. Cl. G09G 5/00; G06F 3/02; H03M 11/00

(52) U.S. Cl. 345/169; 341/22

(57) ABSTRACT

Rules of operation for a first keyboard having a small number of keys based which exploit user familiarity with the physical layout and operation of a second keyboard having a much greater number of keys. The second keyboard is a familiar keyboard such as a QWERTY keyboard or a phone keypad, and the rules of operation for the first keyboard reflect the location of the keys of the second keyboard that are used to enter specific text characters and how those keys are operated to enter them. This method can apply to keyboards operating under predictive text algorithms, and enables modification of existing predictive text algorithms by enabling correction of incorrect guesses starting at different points in a guessed word, including from the first letter in the word. The rules of operation enable construction of keyboards with very few keys that are easy to master and efficient to operate.

### CROSS REFERENCE TO RELATED APPLICATIONS

This application is a continuation-in-part of PCT Patent Application No. PCT/US2008/076201 filed Sep. 12, 2008 entitled “Highly Compact Keyboards” which claims the benefit under 35 U.S.C. 119(e) to U.S. Provisional Patent No. 60/971,613 filed Sep. 12, 2007. Each of the above applications is incorporated herein by reference.

### FIELD OF THE INVENTION

The present invention relates to keyboards and keypads for text entry, and in particular to compact and ultra-compact keyboards, the touch-typing and predictive text entry rules for operating such keyboards, and methods creating such operating rules for such keyboards.

### BACKGROUND OF THE INVENTION

There is a need for new compact data entry devices for portable electronics. Not all such devices are big enough to accommodate either a full compact keyboard such as found on the Blackberry or even the 12-key keypad found on most wireless phones, and such keyboards if added to such devices can force a reduction in display screen size, increase the size and weight of the device, and raise its cost to manufacture. Moreover, many electronic devices on the market already have other types data entry mechanisms incorporated into them (such as that found on the Palm Tungston E consisting of four keys and a pointing device or four-way controller, that found on the Palm Z22 consisting of two keys and a pointing device, that found on many digital cameras comprising a four-way controller comprising a set of four directional buttons surrounding a center button, and that found on the Apple iPod consisting of a touch-sensitive click-pad) which cannot currently be used directly as alphanumeric text entry devices, and especially not as touch-typing text entry devices (i.e., where the user does not have to look at the display to be able to enter a particular string of characters but can simply memorize and execute a specific and fixed sequence of actions to enter each data string).

There is therefore a need for ways to enable the control and non-text data entry mechanisms found on portable electronic devices such as those described above to operate as keyboards and as numeric and alphanumeric keyboards in particular. The use of such electronic devices would be improved if users could enter alphanumeric text to label a song, photo or video clip, search for contacts, songs, photos and video clips by their labels or names, compose text-messages, enter data such as contact information, or choosing menu choices to control the device. The addition of an alphanumeric keyboard would also expand the types of functionality that could be added to those devices.

Many new keyboards have been proposed, but most have failed because people resist learning new typing algorithms. Therefore, in order that users do not have to start from scratch to learn how to operate a new keyboard, the new keyboards should build on user's familiarity with common keyboards such as standard alphanumeric keyboards, calculator keyboards and 12-key phone keyboards by emulating them as much as possible. Thus, there is a need for compact keyboards that build upon user's familiarity with known keyboards such as laptop keyboards, phone keypads, calculators and other common keyboards, including those with more than one data string per key such as the multi-tap keyboards found on phone handsets. There is also a need for compact keyboards that can be used to enter text in any language, including character-based languages such as Chinese, and which can enter the very large sets of data strings that such keyboards may require using only a few actuators. There is a need for a way to create rules for operating compact keyboards of any configuration that are easy to learn for users of other, emulated keyboards, and even for users of other systems of organizing symbols and characters.

Multi-tap keyboards are designed to allow a user to operate a single key to enter a text character into a typable device. The key operated reduces the universe of possible text characters to be entered from the entire set of text characters the keyboard can enter to those enterable using the operated key. Tapping one or more times on the multi-tap key reduces the universe of possible text characters to one. To reduce the number of text characters that each key is capable of entering so that the number of taps of the key to exactly specify a particular text character is small (four or five at most), multi-tap keyboards typically have a lot of keys which are typically arranged in rows and columns. There is a need for highly compact keyboards with a small number of keys, such as a keyboard consisting of the ubiquitous 4-way navigation device, that are easy, even intuitive to learn and operate. Predictive text algorithms help make multi-tap keyboards more efficient, and there is a need for predictive text algorithms appropriate for such highly compact keyboards.

### SUMMARY OF THE INVENTION

Before proceeding with a description of the invention, several terms used herein need to be defined, and a detailed explanation of them needs to be provided.

As used here, “data string” refers to any character, alphanumeric character, string of alphanumeric characters, symbol (such as punctuation, mathematical operators, text delimiters, and anything else that can be entered using a keyboard or entry or control mechanism of any sort), strings of symbols, ideograph, string of ideographs, function, series of functions, operation, string of operations, and any other element of data or command that can be entered using any type of keyboard. “Text character” is used to refer to that set of data strings that the emulated keyboard can be used to enter in text entry mode, and are typically punctuation, symbols, letters, and numbers. With many keyboards, text characters are simply letters, numbers, and punctuation.

As used here, the term “keyboard” includes in its meaning any device operated by a user to enter data strings into an electronic device, whether or not any keys are actually employed. A keyboard is a component of a communications and/or computing device which transforms physical movement by an operator into symbol sequences. These include, but are not limited to, standard alphanumeric keyboards used for typing alphabet-based languages, Asian language keyboards used for typing ideograph- or character-based languages such as Mandarin Chinese, numeric keypads such as those found on calculators, phone keypads such as those found on cellular phone handsets and touchtone telephones, and any of the other keyboards disclosed or emulated here. Keyboards comprise at least one input device which is responsible for the transformation of some subset of the physical motions operative to activate the keyboard into a signal to the keyboard or the device to which it is attached. The terms ‘key’, ‘actuator’, ‘button’ and ‘actuation position’ are used interchangeably with the term ‘input device’. The physical movement used to operate a keyboard is typically in the form of motion of fingers and/or thumb or of a hand-held stylus. This definition extends to other bodily motions, such as head, tongue, or eye motions which might serve to signal a choice of symbol from the keyboard. Common input devices are keys, such as those found on cell phones and computer keyboards, mice, buttons, touch sensitive pads and defined portions thereof, patterns of movement on touch pads and in space, rings and buttons, bubble switches, click pads, click wheels, push buttons, pointing rings and disks, 4-way navigation devices, pointing sticks, and toggle switches. Newer actuators include virtual locations in 3-D space, specific movements of devices or body parts in 3-D space (using multi-axis inertial sensors to determine which actuation is meant), and others. As used here, to “actuate” is what a user does to an input device that is part of a keyboard to enter data strings into a typable device, and includes in its meaning any engagement of or action upon, such as pressing, tapping, depressing, moving in 3D space, clicking, flicking, touching, clicking, and actuating an actuator that causes a signal to be generated for encoding by the typable device.

A device comprising a keyboard according to this definition can be referred to as a “typable device”. The disclosed keyboards are part of typable devices. Keypads can be keyboards or they can be part of keyboards. In many cases keypads are an organized arrangement of keys, often those keys used for entering text characters. Examples of keypads are the 12-key keypads found on cell phones (4 rows of three keys each) and calculator keypads of which there are many forms. In the following, the keyboards typically comprise keypads and other actuators not part of the keypads. By typable device we understand not just the physical device containing the keyboard, but the entire communication system in which this typable device is embedded, the limits of that system defined by dependence on input from the keyboard. In the case of a typable device in which input symbols appear directly on a display which is physically part of the typable device, the limits of the system are clear and defined by the physical perimeters of the device. In more general cases, in which for example the typable device includes a telephone handset sending information to a central computer, the central computer being responsible for decoding or otherwise acting on the textual information communicated from the handset, then the “typable device” must be understood to include the central computer, as configured to operate in the required manner by software built into the typable device or keyboard. Touch typing is the process by which the symbol sequences are generated from the keyboard using only or predominately kinesthetic rather than visual or auditory feedback.

It will be appreciated that each of the at least one input device comprised in a keyboard can take a wide variety of physical manifestations. The essential feature of an input means is that it permits an operator to send a unique signal to be encoded by the keyboard. Typing is the process of sequentially selecting at least one input means in order to select sequences of subsets of symbols from the set of symbols which can be encoded by the keyboard. It is to be appreciated that well-known handwriting recognition software permits a kind of typing in which the input means translates a collection of drawing motions into the selection of a subset of a set of symbols.

The purpose of operating an input device is to communicate user intentions to a logic element of the keyboard or typable device. When using the input device to enter text, the user intentions being communicated are generally what data string the user wants to enter (e.g., a ‘1 ’ or an ‘X’). Sometimes user intentions can be communicated with single signal containing all information necessary to communicate the user's intention, but sometimes a plurality of signals are needed, each communicating one of the pieces of information necessary to communicate the user's intention.

Compact keyboards with a paucity of keys, each of which is used to type more than one data string, typically require multiple signals to communicate user intentions. Operating a particular input device on a particular keyboard, such as the 6 key of a 12-key phone keypad, generates a unique signal that communicates one piece of information: that that particular input device (e.g. the 6 key) was operated. This signal is processed by some logic element of the keyboard or typable device. However, the one piece of information communicated by actuating the 6 key, which key was operated, does not communicate enough information for the logic element to definitively determine the user's intention since the same key can be operated to enter multiple data strings. More information is needed. With multi-tap keyboards such as those described below, the logic element is capable of interpreting a series of closely spaced (in time) signals from the input device as a single expression of user intentions. For example, a series of three rapid presses of the 6 key on a phone keypad is interpreted by the logic element as the instruction to enter an ‘o’ into the text displayed on the device's screen. Such operation of an input device communicates more than one piece of information; in the previous example, simply using the 6 key communicates that the data string to be entered is an ‘m’, an ‘n’, an ‘o’ or a ‘6 ’, and operating the 6 key three times communicates that the data string the user wants to enter is the third data string in the tap order: using both pieces of information, the logic device can definitively determine that the data string the user intends to enter is ‘o’. The “tap order” is the ascending order of number of taps required to enter a data string using a multi-tap key; entering the first data string in the tap order requires one tap of the key, entering the second data string in the tap order requires two taps of the key, and entering the nth data string in the tap order requiring n taps of the key. If the logic device is capable of distinguishing the duration of actuations of an input device, operation of an input device can communicate at least one more piece of information. Patterns of actuations can communicate more information.

“Parameter input mechanism” and “parameter input means” or “PIM” are terms used to refer to a means by which one piece of information is communicated by selective operation of an input device, such as the input device used, the number of actuations of that input device, and the duration of the actuations or pattern of actuations of different duration. They are referred to as parameter input means because each communicates a single input parameter or piece of information about the data string the user wants to enter.

An “input parameter” or “IP” is one of the pieces of information required by the typable device to interpret user intents, and each input parameters can have multiple values (e.g., one of several possible keys, the number of keystrokes, whether an actuator, such as the shift key, is actuated or not). For a multi-tap keyboard, three input parameters are required for the logic element of the typable device to determine definitively and exactly which data string a user intends to enter. They are key used, number of taps of that key, and whether the shift key was pressed prior to operation of the key; the key used tells the typable device which subset of data strings the data string the user wants to enter is a part of, the number of actuations of the key tells the typable device which of the data strings in that subset is intended, and whether the shift key was pressed in advance tells the typable device whether the data string, if it is a letter, is capitalized—default is lowercase unless the default has been changed by engaging Caps Lock.

“Entry mechanism” or “data string entry mechanism” is a term used to refer to the set of parameter input means used in operation of a single input device is a data string entry mechanism. Continuing with the same example, the data string entry mechanism of the 6 key utilizes two parameter input means, the choice of key actuated and the number of times it is actuated, and the entry mechanism is operation of the two parameter input means (i.e., one or more taps of a particular key within a certain time limit). The shift key is a separate entry mechanism with a single parameter input means (ignoring for the moment that some shift keys can be operated to engage Caps Lock or for other input).

The compact keyboards capable of entering large numbers of data strings relative to the number of keys they have, such as the ultra-compact keyboards described herein, often need more pieces of information to correctly interpret the user's intentions than can be communicated by operation of a single input device, even if the input device can function as an entry mechanism with three parameter input means. The approach used in the present invention to enable the user to provide enough information is to employ sequences of entry mechanisms as the default mode for entering data strings. These sequences of entry mechanisms, and of the parameter input means that comprise them, are termed “actuation sequences”. Entry mechanisms are used in order in the actuation sequences, with the first entry mechanism used referred to as the “primary entry mechanism” or “PEM”, the second entry mechanism referred to as the “secondary entry mechanism” or “SEM”, and the third entry mechanism referred to as the “tertiary entry mechanism” or “TEM”. Unless a predictive text algorithm is in operation, each actuation sequence provides a unique set of input parameter values that uniquely identify the data string a user wants to enter.

The set of unique actuation sequences corresponding to the set of data strings a particular keyboard is able to enter into a typable device is termed the keyboard's “keyboard setup”. The same keyboard can have multiple keyboard setups; for example, many English language keyboards can be switched to other languages, and phone keypads often operate under an alphanumeric keyboard setup and a numeric keyboard setup. In general, keyboard setups can be expressed in the form of a table, often a multi-dimensional table, of which many examples are given below for the keyboards disclosed here. When properly constructed and labeled, a table for a keyboard setup teaches how to enter a data string. Each data string occupies a cell in the table and where a data string is located in the table provides enough information to determine the actuation sequence to enter that data string, with the row in which the data string is found typically giving the PEM actuator and type of actuation (such as the number of actuations), and the column in which the data string is found giving the SEM actuation option and type of option to be executed. Most tables are divided into at least two sections to add a fourth dimension.

A method for creating easy-to-learn and -remember rules for touch typing using a compact keyboard having any physical configuration is disclosed. The method disclosed enables a compact keyboard to emulate a familiar, less compact keyboard. For example, this method enables a keyboard consisting of a 4-way navigation device such as those found on many digital cameras to emulate a QWERTY keyboard and a 12-key phone keypad among other keyboards. For a compact keyboard (the emulating keyboard) to emulate a less compact keyboard (the emulated keyboard) means that the emulated keyboard serves as a mnemonic for how to use the emulating keyboard. Using a QWERTY keyboard as the emulated keyboard familiar to most users, in using the emulating keyboard the user can simply say to himself, “since I enter ‘f’ using the 4^{th} key from the left end of the second row of the QWERTY keyboard, then the actuation sequence (sequence of keystrokes or other actuations of actuators) to enter it using the emulating keyboard is by doing X” (for example, pressing a particular key of the emulating keyboard some number of times or pressing a first actuator some number of times and then pressing a second actuator some number of times). Or if the disclosed keyboard is emulating a 12-key multi-tap phone keyboard, the user can say to himself, “since I enter ‘u’ by tapping the middle key in the third row of the phone keypad twice, then the actuation sequence to enter ‘u’ using the emulating keyboard is by doing Y” (for example, by pressing a specific actuator some number of times). The method is based on the principal that since one person can communicate to another how to enter a data string on a keyboard by describing the exact location of the key on the keyboard used to enter the data string and how that key is used to enter the data string, this same information would, if communicated to a typable device, provide sufficient information for the typable device to determine which data string to enter.

The method requires first choosing or designing a compact keyboard that will be used to emulate a larger, more familiar keyboard. Any familiar keyboard may be emulated, and as different users are familiar with different keyboards, the number of possible familiar keyboards to be emulated is large and includes such keyboards a QWERTY, phone keypads, Blackberry SureType, DVORAK, and standard keyboards in any language. Next, the keyboard that will be emulated is chosen. The emulated keyboard should be familiar to many users and have many more keys than the compact keyboard doing the emulating (2, 3, 4, 5, or more times as many). Sometimes it makes sense to reverse these two steps and choose the keyboard to be emulated first and then design or choose the compact keyboard to emulate it. The third step is to identify a subset of keys of the familiar emulated keyboard that the compact emulating keyboard will actually emulate (the subset can include all the emulated keyboard's keys).

The fourth step involves identifying a subset of the actuators comprising the compact keyboard that will be used to emulate the subset of keys of the emulated keyboard that are to be emulated. Just as some keys of a QWERTY keyboard or a phone interface are used for text-related functions other than actually entering text characters, so to can some of the keys of the emulating keyboard be used for text-related functions other than text entry while others are dedicated to text entry. Next a set of input parameters and a range of values for them. If the values for all the input parameters are known, how each key data string is entered using the emulated keyboard will be known. Among the input parameters commonly used are those that identify the physical location (such as its row and column) of the specific key of the emulated keyboard used to enter a particular data string. The range of values of the input parameters will reflect the structure and operation of the emulated keyboard. This is one reason the rules to operation of the keyboards disclosed here are easy to learn. Sometimes rows or columns are broken into sections and that becomes an input parameter. Other input parameters have to do with how the data string is entered using the identified key. These include whether the key is actuated multiple times to enter the data string (as with multi-tap keys) and whether the key is held down or otherwise operated differently. Other input parameters have to do with the use of modifier keys (e.g., shift, Alt, Ctrl), and which one is used in conjunction with the identified key to enter the particular data string and how it is operated.

Next a set of parameter input means for the emulating keyboard are defined. This is often accomplished by separating the keys of the emulating keyboard into two or three mutually exclusive groups and then defining parameter input means involving each. Parameter input means are used to convey input parameter values to the typable device or logic device governing keyboard operation.

The next step is to pair a parameter input means for the emulating keyboard with an input parameter for the emulated keyboard that it will be used to enter. Each input parameter has a number of options or range of values, and the parameter input means that will input it must have at least that many options or be able to enter the same range of values. Each actuator group will constitute an entry mechanism which may enter one or more input parameters.

The next step is to determine an order in which the entry mechanisms will be operated. Once this order is determined and the parameter input means and input parameters have been defined, their ranges have been set, and assignments of parameter input means to input parameters have been made, the actuation sequences for the key data strings will be determined. Next the full set of data strings that will be entered using the emulating keyboard is defined, and adjustments are made to the parameter input means and input parameters and to the range of their values in order to expand the set of available actuation sequences enough to have one for every data string in that full set. Finally, the non-key data strings are assigned to available actuation sequences.

Using this method, easy-to-learn operating rules for compact keyboards having nine, six, five, four, three, and even two keys, or other numbers of actuators, can be created. These rules are then incorporated into or embodied in the operating software of the keyboard or the typable device of which it is a part so that the execution of actuation sequences by a user will result in the typing or entry or display of the intended data string.

To use an emulating compact keyboard whose rules of operation have been created using the just-described method, the user simply follows the rules to self-generate the actuation sequences for those data strings he knows how to enter using the emulated keyboard, and refers to the keyboard setup table or memorizes, how to enter the rest (although display hints and prompts can be used to reduce the need for memorization). Thus, if the user knows that ‘g’ is entered by typing the fifth key from the left in the left-hand section of the second row of a QWERTY keyboard without using the shift key, then entering a ‘g’ using a keyboard that emulates a QWERTY keyboard involves following the rules to specify that that is the location of the key used to enter ‘g’ on QWERTY keyboard and no shift key is used.

The method described above can be extended to keyboards that emulate other things. For example, a cellular phone keypad can be to operate as a Chinese character keyboard by emulating the structure of a Chinese dictionary which organizes Chinese ideographs according to brushstrokes and other characteristics. In this case the user can say: “since the ideograph has X brushstrokes and Y radicals, I enter it by pressing a first appropriate key x times, then a second appropriate key y times.

Also described are compact and ultra-compact keyboards which operate under rules created using the described method. The disclosed keyboards have multiple configurations, and some of the disclosed compact keyboards comprise the control interfaces found on electronic devices such as PDAs, laptops, cameras, security pads or cell phones, which convert that electronic device, if it is not already one, into a typable device, and especially into a touch-typable device.

Also described is an extension of the above method that can be used to create rules of operation to allow a compact keyboard to emulate a larger keyboard operating under a predictive text algorithm. The compact emulating keyboards described can also operate under rules created under the method above to allow both predictive text and definitive text input. The approach described in detail herein can be used to allow any compact keyboard to emulate almost any larger keyboard operating under any predictive text algorithm and to allow almost any set of actuators comprising an electronic device user interface to operate as an alphanumeric keyboard under a predictive text algorithm. These include keyboards that specifically emulate phone text-entry interfaces comprising a 12-key phone keypads operating under word-by-word predictive text (PT) algorithms (such as T9, iTap, Letterwise, TenGo and Blackberry's SureType algorithm).

Predictive text algorithms and the software comprising them and the typable devices operating under the software comprising the predictive algorithms can be improved by replacing the Next key common among predictive text software for scrolling through a list of predictions with a Tap Order key which permits a user to complete an actuation sequence for an ambiguously entered data string to provide additional information the predictive text algorithm can use to make better guesses. The Tap Order key is possible easy to implement on emulating keyboards operating under some keyboard setups because one key is operated to enter the values of the input parameters specifying the key of the emulated multi-tap keyboard used to enter a data string (and any others entered using that same key), and another key is used to specify that data string's position in the tap order of the specified key. This fact makes it easy for the operating software to distinguish entry of a new data string from correction of an already entered one.

The Tap Order key can replace or augment the Next key used by current predictive text software. In these embodiments, the Tap Order key is an auxiliary key separate from the keys used to enter the text characters. If the predictive text software guess after a key has been specified is incorrect, the user can operate the Tap Order key to indicate the position of the intended data string in the tap order of that key.

### BRIEF DESCRIPTION OF THE DRAWINGS

The foregoing and other features and advantages of the invention are described in detail below, in conjunction with the accompanying drawings, which are briefly described as follows.

FIG. 1 is a schematic illustration of an emulating keyboard.

FIG. 2 is a table showing one example of defined input parameters for a QWERTY keyboard.

FIG. 3 shows in tabular form a keyboard setup for the keyboard in FIG. 1 for emulating a QWERTY keyboard.

FIG. 4 shows the parameter input means and input parameter definitions and assignments for the keyboard setup in FIG. 3.

FIG. 5 shows in tabular form a keyboard setup for the keyboard in FIG. 7 for emulating a 12-key phone keyboard.

FIG. 6 is an example of input parameter definitions for a 12-key phone keyboard.

FIG. 7 is a schematic illustration of an emulating keyboard having four keys.

FIG. 8 is a table showing an example of parameter input means and input parameter definitions and assignments for emulating a 12-key phone keypad.

FIG. 9 is a table showing another example of parameter input means and input parameter definitions and assignments for emulating a 12-key phone keypad.

FIG. 10 is a keyboard setup in tabular form for a keyboard emulating a 12-key phone keypad associated with the parameter input means and input parameter definitions and assignments shown in FIG. 9.

FIG. 11 is a schematic illustration of an emulating keyboard having five keys.

FIG. 11A is a schematic illustration of another emulating keyboard having five keys.

FIG. 11B is a table showing an example of parameter input means and input parameter definitions and assignments for the emulating keyboard shown in FIG. 11A.

FIG. 11C is a keyboard setup in tabular form for a keyboard emulating a 12-key phone keypad associated with the parameter input means and input parameter definitions and assignments shown in FIG. 11B.

FIG. 12 is a schematic illustration of an electronic device incorporating an emulating keyboard.

FIG. 13 shows another example of defined input parameters for a QWERTY keyboard.

FIG. 14 is a schematic illustration of an emulating keyboard having six keys.

FIG. 15 is a table showing another example of parameter input means and input parameter definitions and assignments for emulating a QWERTY keypad using the keyboard in FIG. 14.

FIG. 16 is a keyboard setup in tabular form for a keyboard emulating a QWERTY keyboard associated with the parameter input means and input parameter definitions and assignments shown in FIG. 15.

FIG. 17 is a schematic illustration of an electronic device incorporating an emulating keyboard.

FIG. 18 is a schematic illustration of an emulating keyboard having three keys.

FIG. 19 is a keyboard setup in tabular form for emulating a QWERTY keyboard using the keyboard in FIG. 18.

FIG. 20 shows an example of defined input parameters for a calculator keyboard.

FIG. 21 is a table showing the parameter input means and input parameter definitions and assignments for emulating a calculator keyboard.

FIG. 22 is a keyboard setup in tabular form for emulating a calculator keyboard using the keyboard in FIG. 14.

FIG. 23 is a schematic illustration of a generic typable electronic device comprising an emulating keyboard and a display.

FIG. 24 is a schematic illustration of a typable electronic device comprising an emulating keyboard having seven actuators, and a display.

FIG. 25 is a table showing the parameter input means and input parameter definitions and assignments for emulating a 12-key phone keypad running a predictive text algorithm.

FIG. 26 is the keyboard setup in tabular form for a keyboard emulating a 12-key phone keyboard operating under predictive text software that is associated with the parameter input means and input parameter definitions and assignments shown in FIG. 24.

FIG. 27 is a keyboard setup in tabular form for the emulating keyboard operating under the keyboard setup in the table in FIG. 25 if the guess of the predictive text algorithm is incorrect.

FIG. 28 is a schematic illustration of a typable electronic device comprising an emulating keyboard and a display.

FIG. 29 is a keyboard setup in tabular form for a keyboard emulating a SureType keyboard running SureType-like predictive text software.

FIG. 30 is shows the five levels of sets of data strings from the set containing all key data strings to the final subsets consisting of individual key data strings.

### DETAILED DESCRIPTION OF THE INVENTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical, and electrical changes may be made without departing from the scope of the present invention. The following description of example embodiments is, therefore, not to be taken in a limited sense.

### Method of Emulating Keyboards and Compact Emulating Keyboards

The method disclosed here can be used to allow a more compact keyboard (the emulating keyboard) to emulate text entry by another less-compact keyboard (the emulated keyboard).

The first step is to choose or design the compact keyboard that will emulate another keyboard. In cases where one wants to transform an electronic device into a typable device (such as enabling text entry into digital cameras using the existing user interface), the design of the emulating compact keyboard may already be determined. In the second step, one identifies a keyboard that the new compact keyboard will emulate.

One criteria is whether the keyboard to be emulated can enter the minimal set of data strings the emulating keyboard must enter. For implementation of the method on the emulating keyboard to have the best results, a familiar keyboard should be chosen (e.g., QWERTY, phone keypad). The emulated keyboard will generally have at least two, three, four, or five times as many actuators as the emulating keyboard so that the emulating keyboard can be as compact as possible. Another criteria in emulated keyboard choice is whether the physical structure of the emulating keyboard and the layout of the keys to be emulated are compatible. Sometimes it will be obvious that there is a lack of compatibility; sometimes the lack of compatibility will not become obvious until one tries to implement the method described in detail below to create an emulating keyboard, its rules of operation, and the software that implements them. The order of the first two steps can be reversed.

The third step is to identify what subset of the keys of the emulated keyboard will actually be emulated by the emulating keyboard. In some embodiments, all keys of the emulated keyboard will be emulated and the aforementioned subset of keys will contain all of the emulated keyboard's keys. Some of the familiar keyboards attractive for emulating are already compact, and the emulating keyboard may emulate all the familiar keyboard's keys and be able to enter all data strings that the emulated keyboard is capable of entering. One example is the 12-key phone keypad which has only twelve keys, all of which are used to enter text characters, and in the embodiments of emulating keyboards described herein, all keys of the phone keypad are emulated. In other cases, however, only a subset of the familiar keyboard will be emulated.

Full-size alphanumeric keyboards often have over 100 keys, and include many keys not absolutely necessary for the text entry. While it is possible using the method disclosed here to create a compact keyboard that will emulate every key of a larger keyboard, the emulating keyboards will typically be used only for limited text entry, not for extended text entry or control of a typable device; therefore, the emulating keyboards only need to be able to enter a subset of the data strings that the 100+ keys of a full-size alphanumeric keyboard can enter. For text entry, the most important data strings are text characters, and especially letters and numbers. On a QWERTY keyboard, there are 36 keys to enter numbers and letters in four rows, the longest two of which contain ten keys. Therefore, in the embodiments of compact keyboards emulating full-size QWERTY keyboards described below, at least the 26 letter keys are emulated, and usually the 10 number keys as well, for a total of 36 keys being emulated. The data strings that can be entered using the subset of keys of the emulated keyboard that are emulated by the emulating keyboard are referred to as the key data strings. The choice of keys to emulate defines the key data strings, even if a modifier key outside of the keys being emulated is used to enter them (e.g., the shift key).

In some cases, it may be desirable for efficiency of data string entry to ‘virtually’ modify the arrangement of keys in the familiar keyboard to be emulated. For example, the 36 keys of the QWERTY keyboard that are often emulated may be rearranged virtually to put the row of number keys below the rows of letter keys. If this is done, it will be the new modified, virtual version of the familiar keyboard that will be emulated, not the actual keyboard. This will be explained in more detail below.

The fourth step is to identify a subset of the keys of the emulating keyboard that will be used to enter the key data strings into the typable device. An emulating keyboard may have more keys and other actuators than is necessary to emulate the subset of keys of the emulated keyboard that are used to enter the key data strings into a typable device. Any extra keys or input means can be used for text-entry related functions such as delete, backspace, and enter, or for navigation about the text (such as move the cursor right or left). The extra keys can also be used to enter certain key data strings, like spaces, that are used frequently. Text entry will be much more efficient if a dedicated key is used for entering spaces rather than requiring multiple actuations of one or more keys to enter a space.

The fifth step in implementing the method is to define a set of two, three, four, or more input parameters and ranges of values for each. These input parameters must be able to specify how each of the key data strings is entered using the emulated keyboard. If the row is an input parameter, and there are three rows, the range of values for the row input parameter will be 1 to 3. For a simple keyboard like a calculator keypad, the only input parameters needed may be the row and column, or row and position in the row, of the key used to enter a particular data string. If the emulated keyboard is a multitap keyboard, such as that found on phones incorporating a 12-key phone keypad, an input parameter indicating a data string's place in the tap order of the key used is needed. If a modifier key such as the shift key is used to enter some key data strings, an input parameter that indicates whether a modifier key is used will be needed. Among the input parameters (IP) that can be used are (all refer to the emulated keyboard):
“Row-IP”—the row in which the key that enters a specific data string is located
“Column-IP”—the column in which the key that enters a specific data string is located
“Section-IP”—the section of the row in which the key that enters a specific data string is located
“Position-IP”—the position of the key that enters a specific data string in a row or section of a row
“Tap order-IP”—the position of the key in the tap order of a key
“Shift-IP”—whether the shift key is used in conjunction with the indicated key to enter a specific data string
“Ctrl-IP”—whether the Ctrl key is used in conjunction with the indicated key to enter a specific data string

Many of the input parameters will have ordinal number values, and in general counting will start from the top (such as for row-IP) or the left (such as for column-IP and position-IP). Other input parameters may be necessary for emulating keyboards wherein the keys are not laid out in rows and/or columns.

The sixth step is to define the set of parameter input means that the emulating keyboard will use to enter the set of input parameters selected in the first step. The number of parameter input means must at least equal the number of input parameters. Possible parameter input means are which key from a first group of keys is used, the number of times such key from the first group is actuated, which key from a second group of keys is used, and the number of times the key from the second group is actuated. Only if there is more than one key in a group can the choice of key serve as a separate parameter input means. Defining sufficient parameter input means for a compact keyboard usually requires segregating the keys of the emulating keyboard into at least two mutually exclusive groups. Among the parameter input means (PIM) typically available on a compact keyboard are:
“Key choice-PIM”—which key is used out of a group of keys
“Number-PIM”—how many times the key is actuated
“Last hold-PIM”—holding the last actuation in the actuation sequence for at least some predetermined time or not
“First hold-PIM”—holding the first actuation in the actuation sequence for at least some predetermined time or not
“Last PEM hold-PIM”—holding the last actuation of the PEM execution
“Mod key-PIM”—using a modifier key in conjunction with the key being used to enter a data string

The seventh step is to assign each parameter input means of the emulating keyboard to the entry of a particular input parameter of the emulated keyboard. The parameter input means assigned to input an input parameter must as many options, variations or values as the input parameter. That is, it must be able to communicate sufficient information to be able to exactly specify the input parameter value. For example, if one input parameter is the number of rows and there are four, the input parameter can have a four different values (i.e., 1, 2, 3 and 4), and the parameter input means must be able to communicate at least four pieces of information; if the parameter input means is which of two keys in a group is actuated, the choice of keys cannot be used to input the row number. If the parameter input means defined in the second step are inappropriate to the emulated keyboard, returning to step 2 and defining a new set of parameter input means, returning to step 1 and defining a new set of input parameters, or even redesigning the emulating keyboard or choosing a new keyboard to emulate may be required.

The eighth step is to determine the order in which parameter input means will be used to enter input parameters. While operating the various parameter input means in a fixed order is not strictly required in all cases, it makes the rules of operation easier to learn and remember. These sequences of user operation of parameter input means are referred to as actuation sequences. Unless a predictive text algorithm is being used, each actuation sequence will uniquely identify a specific data string and how it is entered using the emulated keyboard. By executing an actuation sequence using the emulating keyboard, a user can enter that data string. Since the same key often serves as more than one parameter input means, all parameter input means utilizing the same key must be adjacent in the order of the actuation sequence. To simplify the description below, parameter input means entered using the same key will be considered part of a single entry mechanism. The first entry mechanism in an actuation sequence will be referred to as the primary entry mechanism or PEM, the second entry mechanism in an actuation sequence will be referred to as the secondary entry mechanism or SEM, and the third entry mechanism in an actuation sequence will be referred to as the tertiary entry mechanism or TEM. Therefore, the actuation sequence consists of a PEM actuation, a SEM actuation, and a TEM actuation. If necessary there can be additional entry mechanisms. Also, in some actuation sequences, the SEM, TEM or even the PEM may not be utilized and the actuation sequence may consist of a PEM actuation only or PEM and SEM actuations only. This non-use of an entry mechanism in an actuation sequence is sometimes referred to below as the no-actuation option for that entry mechanism. The term PEM, SEM or TEM actuation means that the one or more parameter input means associated with the PEM, SEM, or TEM are executed to input their related input parameter.

Once the parameter input means and input parameters are defined and one parameter input means is assigned to enter each input parameter, the actuation sequences to enter the key data strings are determined. This is because the location on the emulated keyboard of the key to enter a key data string and how to operate that key to enter that data string are fixed, and the input parameters merely describe that reality. Parameter input means are merely the way the emulating keyboard communicates the information necessary to fully describe that reality. This is one of the great advantages of compact keyboards emulating a familiar keyboard using the disclosed method; if a user knows how to use the familiar emulated keyboard, the user, after learning the few rules embodied in the choice of parameter input means and their order of use, will be able to figure out the actuation sequence for entering any of the key data strings.

The ninth step is to define the full set of data strings to be entered using the emulating keyboard and make the adjustments to the parameter input means, input parameters and their values necessary to create enough actuation sequences to enter them. The full set will include the key data strings and any other data strings that the designer wants the emulating keyboard to enter but which the emulated keyboard either does not enter or which are not entered using its emulated subset of keys. If the keys being emulated are not in a regular arrangement (such as in rows all having the same number of keys), there may be defined actuation sequences that are not being used because they fall within the space defined by the input parameters and the parameter value ranges necessary to emulate the keys which enter the key data strings, are not used for a key data string and can therefore be used for another data string. Defined actuation sequences are those having input parameter values within the range required for entering key data strings, and in some cases not all are used for key data strings. If the number of data strings in the full set of data strings the designer wants the emulating keyboard to enter is greater than the number of defined actuation sequences, the number of available actuation sequences can be increased by increasing the range of acceptable values for the parameter input means already in use or by adding addition parameter input means to actuation sequences. Making either of these changes has the effect of increasing the size of the ‘virtual keyboard’ that is defined by the set of available actuation sequences, such as by adding a new row by changing the range of acceptable values for the row-IP from 4 to 5, or adding an entire new level by using an additional input parameter adding a TEM or quaternary entry mechanism, such as for example by using Ctrl-IP with two values. In effect, the virtual keyboard defined by the set of possible actuation sequences can be of infinite size, so there is no limit to the number of data strings that the emulating keyboards to which the actuation sequences apply can enter, although the number that is practical to enter is limited.

The tenth step is to assign non-key data strings to available actuation sequences. Defining an actuation sequence involves selecting a value for each of its input parameters. The set of data strings that can be entered using an emulating keyboard and the set of actuation sequences that will enter those data strings are referred to here as a keyboard setup. Keyboard setups can be organized into a table which can then be used as a guide for data string entry. One way to assign actuation sequences is to create a table describing the keyboard setup for the emulating keyboard, then first filling in cells for the key data strings (these are fixed) and then putting the remaining data strings into the table, one in each cell.

The order of steps in the method is not absolutely fixed. As noted previously, the first two steps can be reversed. Also, a designer may define the parameter input means as part of or even prior to designing the emulating keyboard. A keyboard manufacturer may even start with a set of input parameter-parameter input means and find emulating and emulated keyboards appropriate to them.

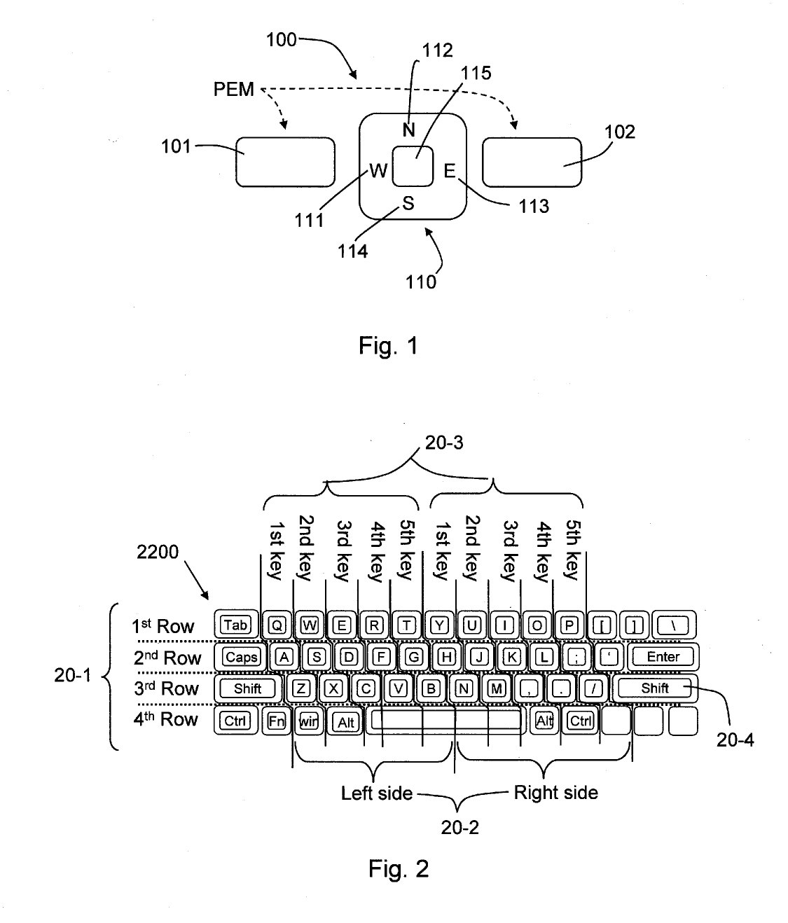

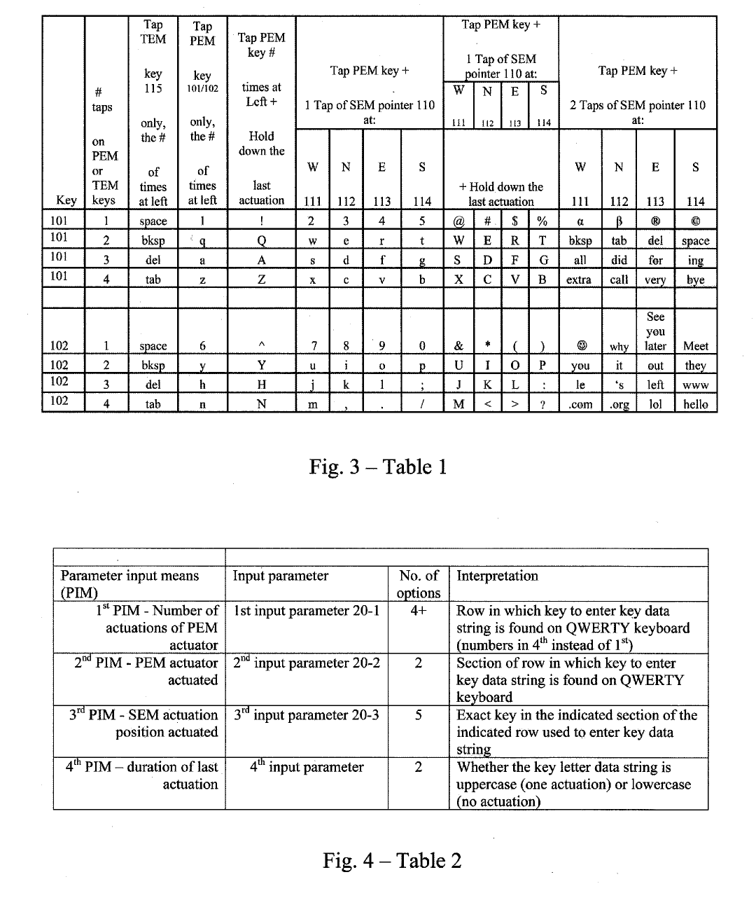

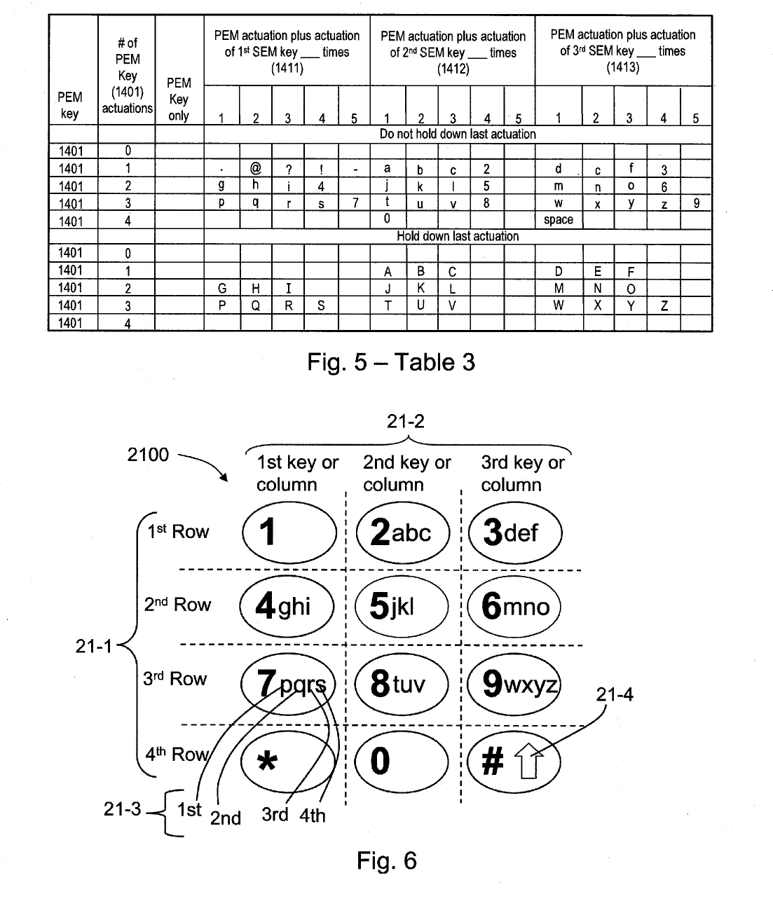

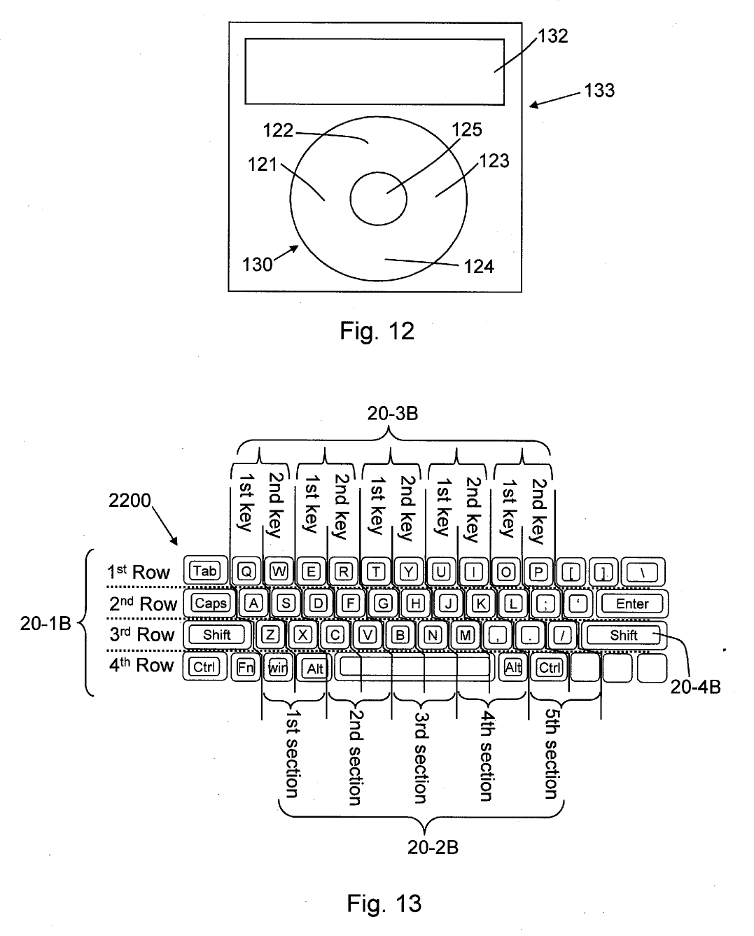

The eighth and ninth steps are optional. Often a keyboard designer will be happy to have the emulating keyboard enter only the key data strings. While this does not take full advantage of the method and its ability to expand the set of data strings that can be entered in a structured and easy-to-learn way, the key data strings of the example QWERTY keyboard 2200 in FIG. 2 and 12-key phone keyboard 2100 in FIG. 6 are sufficient for most text entry needs. The first example below which results in the keyboard setup in Table 1 shown in FIG. 3 is the only example where all steps are completed and the keyboard setup has no unassigned actuation sequences for the range of values of the input parameters used.

To enter a data string using an emulating keyboard operating according a keyboard setup created by following the steps above, the user executes the actuation sequence for entering the desired data string. As a user executes an actuation sequence, a logic unit evaluates the input parameters received and any pauses between actuations to determine when one actuation sequence has been completed, and also when a new actuation sequence has begun. If more than a certain amount of time has passes since the last actuation, the logic unit will recognize that user input of an actuation sequence has ended, and will determine whether the completed actuation sequence is valid. In some cases, if the user operates a key that is part of a group of keys used earlier in actuation sequences than the last key actuated, the logic unit will recognize the last actuation as part of a new actuation sequence, and the series of actuations preceding it and occurring since completion of what was previously the last completed actuation sequence constitute a newly completed actuation sequence. Once the logic unit judges the actuation sequence complete, it evaluates the input parameters input and accumulated, and generates the appropriate entry or error message. Input modes using sequences of keystrokes are familiar to those skilled in the art, and the mechanisms and approaches used in other devices can be used with the preset invention.

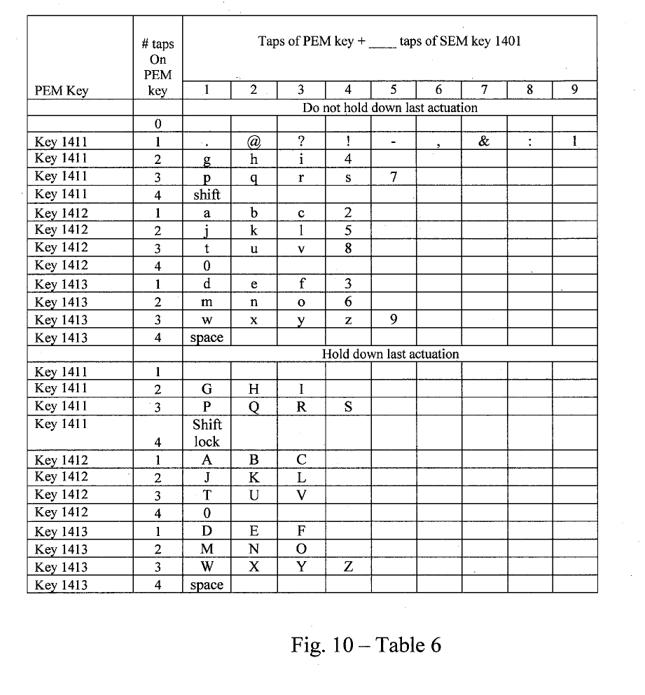

There is another way to look at emulating keyboards operating according to a keyboard setup created using the method above. A set of key data strings is typable by the emulating keyboard. Each of the input parameters can be used to separate the full set of key data strings into subsets of data strings having the same value for that input parameter. After separating the full set into a subset using one input parameter, the subsets created can themselves be separated into subsets of data strings having the same value for another input parameter. Each time this is repeated, the subsets get smaller until all the input parameter have been used; at that point the subsets each have one data string. None of the data strings have the same value for all input parameters since each has a unique actuation sequence. Using keyboard 1400 emulating a 12-key phone keypad and operating under the keyboard setup in Table 6 in FIG. 10 as an example, the full set of key data strings is: (.@?!-,&:1gGhHiI4pPqQrRsS7 shift aAbBcC2jJkKlL5tTuUvV80dDeEfF3mMnNoO6wWxXyYzZ9 space).

The first input parameter, column-IP, divides the full set of key data strings into three subsets, each subset comprising data strings typed with the keys located in the same column of the 12-key phone keypad: (.@?!-,&:1), (gGhHiI4), (pPqQrRsS7), (shift), (aAbBcC2jJkKlL5tTuUvV80), (dDeEfF3 mMnNoO6wWxXyYzZ9 space). The second input parameter, row-IP, divides each of these subsets four subsets, each containing data strings typed using keys located in the same row and column: (.@?!-,&:1), (gGhHiI4), (pPqQrRsS7), (shift), (aAbBcC2), (jJkKlL5), (tTuUvV80), (dDeEfF3), (mMnNoO6), (wWxXyYzZ9), and (space). The third input parameter, tap order-IP, divides the twelve subsets into smaller subsets, each containing data strings having the same position in the tap order and typed using the same key: (.), (@), (?), (!), (-), (,), (&), (:), (1), (gG), (hH), (iI), (4), (pP), (qQ), (rR), (sS), (7), (shift), (aA), (bB), (cC), (2), (jJ), (kK), (lL), (5), (tT), (uU), (vV), (8), (0), (dD), (eE), (fF), (3), (mM), (nN), (oO), (6), (wW), (xX), (yY), (zZ), (9), and (space). The fourth and final input parameter, shift-IP, divides the subsets containing letter data strings into two subsets, one containing the lower case letter, one containing the uppercase letter: (.), (@), (?), (!), (-), (,), (&), (:), (1), (g), (G), (h), (H), (i), (I), (4), (p), (P), (q), (Q), (r), (R), (s), (S), (7), (shift), (a), (A), (b), (B), (c), (C), (2), (j), (J), (k), (K), (l), (L), (5), (t), (T), (u), (U), (v), (V), (8), (0), (d), (D), (e), (E), (f), (F), (3), (m), (M), (n), (N), (o), (O), (6), (w), (W), (x), (X), (y), (Y), (z), (Z), (9), and (space). Now each of the key data strings is the solitary member of its own subset.

In the preceding example, only the key data strings entered using the phone keypad are considered. If all of the empty cells corresponding to full actuation sequences were filled with data strings, there would be more subsets. Also, even though the shift-IP distinguishes upper- and lowercase letters, that input parameter can be used to distinguish between unrelated data strings.

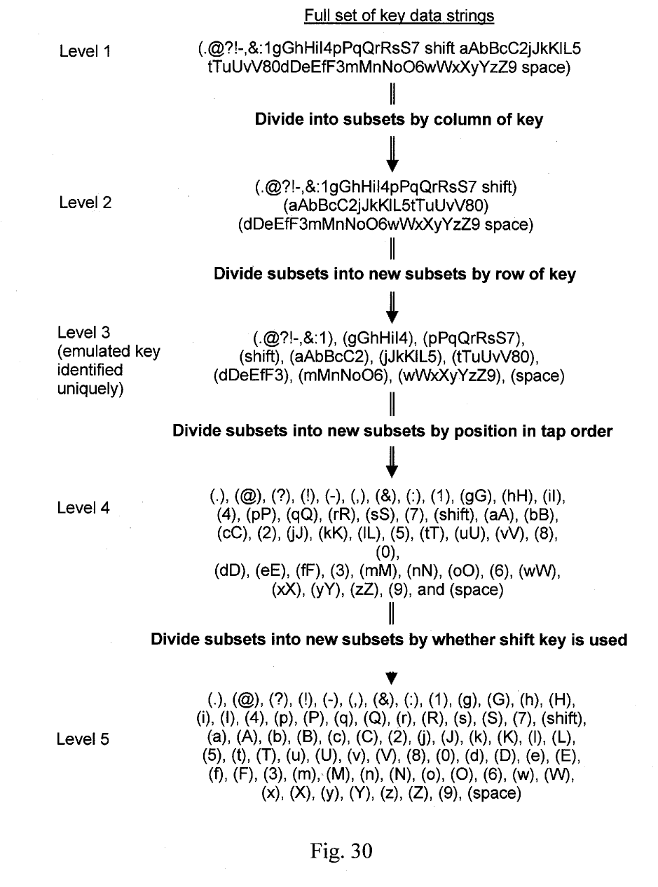

With the keyboard setup in Table 1 in FIG. 3, the full set of key data strings would be divided first into two subsets of data strings entered using the same hand (except for the change of ‘6 ’ to the right hand) or using keys located in the same half of the keyboard. Then the two subsets would be divided into four subsets each consisting of data strings typed using keys located in the same rows of the QWERTY keyboard. The eight subsets would be divided into five subsets each consisting of data strings typed using the same key of the QWERTY keyboard. And finally, the forty subsets would be divided into two subsets each consisting of data strings entered using the shift key or not using the shift key; there are now eighty subsets consisting of one data string each. These five levels of set and subsets is illustrated in FIG. 30.

There are several distinguishing features that the preceding exercise illustrates and which provide advantages to keyboards constructed to operate according to rules generated using the above method. First, the process of identifying the data string is one of starting from the entire set of data strings that can be entered and zeroing in on the specific data string uses physical and operational parameters from the emulating keyboard. In particular, at least two, and in the case of the keyboard setup in Table 1, three, of the parameters have to do with the physical location of the key. Frequent users of the emulated keyboards will be very familiar with their physical layout, and will be able to use that knowledge to operate the emulating keyboard. In all of the embodiments described herein, the physical location of the key of the emulated keyboard used to enter a particular data string is identified exactly. This has the advantage of keeping the rules of operation of emulating keyboards simple to express, easy to learn and intuitive to use.

The second distinguishing feature of the emulating keyboards disclosed here is the number of times the full set of data strings is divided into subsets before each subset consists of a single data string. In both examples, the full set of data strings is divided into subsets four times, meaning that there are five levels of subsets (see FIG. 30). Full size alphanumeric keyboards typically have two subsets of data strings: those entered using the shift key and those entered without using the shift key. Multi-tap 12-key phone keypads have three (key, tap order and whether the shift is used or not) when operating in multi-tap text entry mode, and two when operating under a predictive text algorithm (key and whether the shift is used or not). Keyboards of the preset invention typically have four, and can have more, and at least three when operating in predictive text mode (row, column, and whether the shift key is used). The advantage of this is that an emulating keyboard can have fewer keys and still enter a full set of text characters without becoming difficult to use or extremely inefficient. Some of the keyboard disclosed here are ultra-compact (such as having only three or four keys), yet still able to enter all the text characters enterable by a full-sized keyboard. Being able to construct usable emulating keyboards with so few keys increases the number of devices that can be made typable simply by utilizing the device's existing interface. For example, 4-way navigation devices are found on many electronic devices and these can be used to emulate either a QWERTY or a 12-key phone keypad among others.

Another distinguishing feature of these keyboards is that the number of data strings they can enter can be increased dramatically, but in a highly structured way and without any reduction to the keyboard's efficiency in entering the key data strings. Increasing the range of values for input parameters increases the size of the ‘virtual keyboard’, and increasing the number of input parameters used increases the number of levels of the emulating keyboard (operating a shift key on a QWERTY keyboard shifts from the lowercase, no-shift level to the uppercase, shift-key level of the keyboard where most keys enter different data strings).

A further distinguishing feature of these keyboards is that similarities of the emulating keyboard and emulated keyboard can be exploited to make the emulating keyboard more intuitive to use. For example, if there are three columns of keys on the emulated keyboard, and three keys horizontally aligned on the emulating keyboard, these three keys can be used to indicate the column in which the key on the emulating keyboard used to enter a data string is found. More generally, groups of keys with a general horizontal or vertical alignment can be assigned to an input parameter with a horizontal or vertical alignment respectively, and emulating keyboards can be designed to have layouts of keys conducive to such assignments. Also, many electronic devices, such as digital cameras, are not typable but could be made typable using the method described above to transform the device's input controls into an emulating keyboard. In selecting which of the input controls to use as the actuators for the emulating keyboard, a camera maker can select a group of actuators sharing the same general or exact alignment or orientation as some feature of the emulated keyboard (such as its rows or columns).

Another advantage is that it is easy to construct multiple keyboard setups for the same compact keyboard. For example, a single emulating keyboard can emulate a QWERTY keyboard in one mode, emulate a calculator in another, and emulate a 12-key phone keypad in a third mode.

Another advantage of keyboards operating according to the rules developed using the above method is that it is easy to design emulating keyboards that operate under predictive text algorithms. The

A final advantage of keyboards operating according to the rules developed using the above method is that the emulating keyboards are touch-typable.

The rules for operation created by the preceding method are guide both user operation of the emulating keyboard and design of the emulating keyboard (or of the typable device of which it is a part) operating software. The operating software that implements this method enables a typable device or a logic unit associated with it or the keyboard to interpret user operation of actuators as parameter input means, interpret the parameter input means operation as giving values for input parameters, recognize actuation sequences comprising a set of input parameter values, recognize when one actuation sequence starts and when each is completed, and interpret the input parameters input during execution of the actuation sequence and generate the appropriate signal or signals. How to translate rules of operation of a keyboard into operating software for typable devices and for logic devices such as microprocessors and ASICS is well known by those skilled in the design of keyboards and input devices for typable devices.

### Emulating Keyboards

Several examples of implementation of the method described above will be helpful. We start with applying the method to enable keyboard 100 (the emulating keyboard) shown in FIG. 1 to emulate a full-sized QWERTY keyboard 2200 in FIG. 2. The minimal set of data strings that keyboard 100 must enter are numbers and letters, and so keyboard 100 will emulate the number and letter keys only, four rows with 10 keys in each.

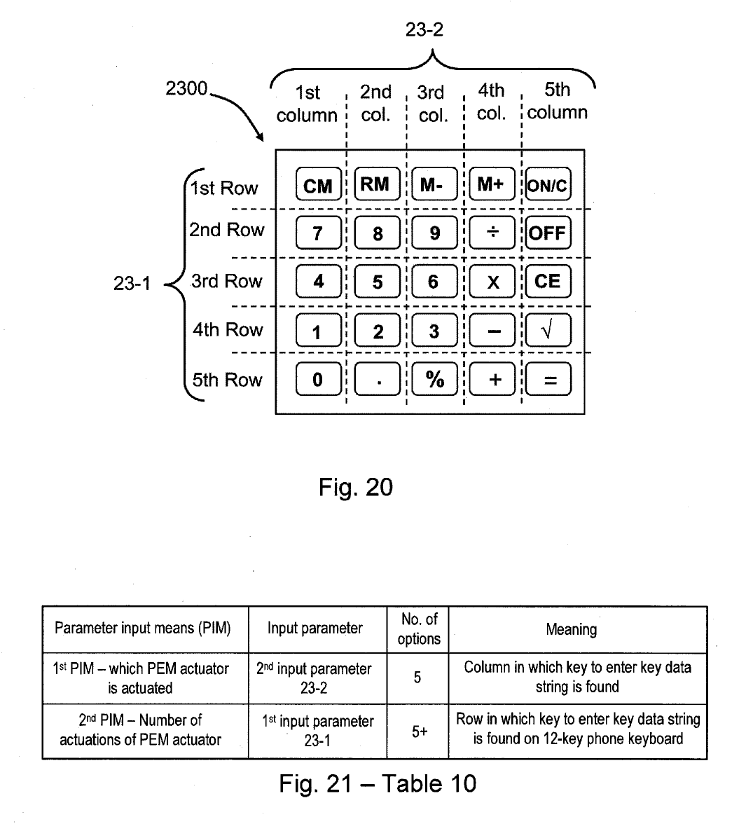

We first identify one possible set of input parameters for data strings. QWERTY keyboard 2200 has three rows of letter keys and one of numbers. The row in which a key to enter a particular data string is located will be the first input parameter 20-1. In touch typing, the keyboard has two sides, those keys typed with the left hand and those typed with the right hand. Since six numbers are touch typed by the left hand, we will deviate somewhat and assign the 6 key to the right section of the number row as is shown in FIG. 20. Which of the two sections of the keyboard 2200 that key to enter a particular data string is in will be the second input parameter 20-2. We choose to create row sections because identifying the position of the last key in a row section will take fewer taps (5) of a key than identifying the position of the key in a full row (10). The third input parameter 20-3 will be the position in its section of the row of the key to enter a particular data string, counted from the left. So that keyboard 100 can type capital letters and punctuation we define a fourth input parameter 20-4, which is whether the shift key is used in typing a data string. These four input parameters suffice to identify the exact key used, and how it is used to enter a specific data string using keyboard 2200, and are illustrated in FIG. 2.

Next we define parameter input means for keyboard 100 in FIG. 1. Four parameter input means must be identified to match the four input parameters defined for the QWERTY keyboard 2200. First, the actuators of keyboard 100 are put into three groups which will be used in the following order: a first group of two keys 101 and 102; a second group consisting of the four actuation positions of pointing or 4-way navigation device 110; and a third group consisting of the button 115. The first group of actuators will serve as the PEM, the second group will serve as the SEM, and the third as the TEM. Specifically, keyboard 100 comprises: a pointing ring 110 comprising four actuation positions west W 111, north N 112, east E 113, and south S 114 with a button 115 in its center and a left key 101 and the right key 102 on either side of it and aligned horizontally. The parameter input means will be PEM keychoice-PIM, PEM number-PIM, PEM last last hold-PIM, SEM keychoice-PIM, and last last hold-PIM.

Now we assign the parameter input means of the emulating keyboard to the input parameters of the emulated keyboard. Because there are two actuators in the first PEM group, we assign the PEM keychoice-PIM to inputting the second input parameter 20-2. Use of actuator 101 indicates that the key to type the desired letter is located on the left side of the QWERTY keyboard 2200, and use of actuator 102 indicates that the key is on the right side. The PEM number-PIM will serve to enter the first input parameter 20-1. There are four defined rows and the number of times the PEM actuator 101 or 102 is actuated will identify the row (actuated once for the first row, actuated twice for the second row, etc.). SEM keychoice-PIM will serve to enter the third input parameter 20-3. Now, there are only four actuators in the SEM group but there are five possible positions for the key in the row. In order to expand the number of actuation options for the SEM actuator, not actuating any SEM actuation position will be considered as one option for the SEM keychoice-PIM. Thus the five actuation options of SEM keychoice-PIM to enter the five options for position in the row are: actuating none of the SEM actuators indicates the first key in the row section is used to enter the data string using the QWERTY keyboard 2200, choosing the W actuation position 111 indicates the second key is used, choosing N 112 indicates the third key is used, choosing E 113 indicates the fourth key is used, and choosing S114 indicates the fifth key from the left end of the indicated section of row is used. Last last hold-PIM will serve to input input parameter 20-4. An alternate embodiment could have used the TEM number-PIM instead of the last last hold-PIM as the parameter input means to enter input parameter 20-4 with the number of times TEM button 115 is actuated indicating whether the shift key is used or not, with no actuation (zero actuations) of the TEM actuator 115 indicating the shift key is not used (i.e., the data string is lowercase), and one actuation of the TEM actuator 115 indicating the shift is used to type a particular data string (i.e., the data string is capitalized). However, the TEM key 115 can be used for other purposes. Table 2 in FIG. 4 shows the assignment of the parameter input means of keyboard 100 to input parameters defined in FIG. 2 for keyboard 2200.

The keyboard setup for keyboard 100 is expressed in Table 1 in FIG. 3. Since keyboard 100 emulates four rows of ten keys each of the QWERTY keyboard 2200, the actuation sequences for entering the data strings entered using those keys, with or without the shift key, are fixed by the choice of PIMS. The eighty unshaded cells of Table 1 in FIG. 3 contain the data strings entered using those forty keys of the QWERTY keyboard 2200. Other keyboard setups would result if different input parameters for QWERTY keyboard 2200 or parameter input means for keyboard 100 are defined, but as long as the same forty keys, with shifting allowed, are being emulated, the actuation sequences for the same eighty data strings will be fixed by the parameter input means used. Because some parameter input means have more options than do the input parameters necessary to define the section of the QWERTY keyboard 2200 being emulated, the keyboard setup can be larger than just for the data strings entered by keys in that section. For example, the SEM number-PIM can be used even though it is not necessary for emulation of the selected section of the QWERTY keyboard 2200. The four columns of shaded cells at the right end of Table 1 in FIG. 3 represent actuation sequences made available for the entry of data strings by employing the SEM number-PIM and using two actuations of one of the four SEM actuators 111, 112, 113, and 114. These data strings are just put in Table 1 in FIG. 3 as examples of data strings that could be entered using the actuation sequences for the cells they occupy, and to provide examples of the wide variety of data strings that can be entered using keyboards of the present invention. The button 115 is not used in the entry of the data strings entered by keys in the emulated section of the QWERTY keyboard 2200 (only six actuators are actually used to emulate keyboard 2200, and can be used as a TEM number-PIM to be used at the end of actuation sequences or alone (with no PEM or SEM actuation preceding it in the actuation sequence) as it is to enter the data strings in the third and shaded column of Table 1 in FIG. 3. There are data strings entered using keys of keyboard 2200 not among the forty keys being emulated which are nonetheless useful. These include space, backspace, delete, and tab. The actuation sequences to enter these four data strings are respectively, one actuation of button 115, two actuations of button 115, three actuations of button 115, and four actuations of button 115. The keyboard setup for keyboard 100 can be expanded by allowing more than four actuations of the PEM keys 101 and 102 or more than two actuations of the SEM actuation positions 111-114 in actuation sequences, or by utilizing the TEM number-PIM at the end of actuation sequences starting PEM and SEM actuations. Table 1 in FIG. 3 would expand (in fact it can be expanded as much as necessary to enable keyboard 100 enter all data strings the designer wants it to be able to enter into the typable device), with each cell representing another available actuation sequence for entering any data string.

Sometimes it may be desirable to make virtual changes to the keyboard being emulated. For example, since letters are used more frequently in entering text that numbers, it would make sense to make the number row of keys of the QWERTY keyboard 2200 the bottom row so that entering the letters using keyboard 100 requires fewer actuations of PEM keys 101 and 102. The keyboard setup if such a change were made would be the same as that in Table 1 in FIG. 3 except that for the order of the rows, with the data strings in rows containing q and y being the first in their sections of the table, the data strings in the rows containing a and h being the second, the data strings in the rows containing z and n being the third, and the data strings in the rows containing 1 and 6 being the fourth rows in their respective sections of Table 1 in FIG. 3. In some embodiments of keyboard 100, the keyboard setup recorded in Table 1 in FIG. 3 is the keyboard setup for the keyboard 100 in numerical entry mode while the keyboard setup suggested above, with the numbers moved to the fourth row of each section of the table (the row requiring four PEM key actuations), being the keyboard setup for text entry mode. Switching from one mode to the other can be accomplished in many ways such as by a dedicated key or by pressing and holding a specific actuator for more than some amount of time.

Table 1 in FIG. 3 also serves as a guide to the actuation sequence required to enter any of the data strings in the table. To use Table 1 in FIG. 3 as a guide, the user follows the instructions in the column headings. The table headers should be interpreted as follows:
“Tap TEM key 115 only, the # of times at left” is an instruction to tap button 115 the number of times in the cell in the column headed “# taps on PEM or TEM keys” which is in the same row as the cell containing the data string is.
“Tap PEM key 101/102 only, the # of times at left” is an instruction to tap the PEM key corresponding to the section of the table in which the cell containing the data cell is found the number of times in the cell in the column headed “# taps on PEM or TEM keys” which is in the same row as the cell containing the data string is.
“Tap PEM key # of times at left+hold down the last actuation” means to tap the appropriate PEM key 101 or 102 corresponding the section of the table in which the row containing the data string is located in the table the number of times indicated in the cell in the column labeled “# taps on PEM or TEM keys” that is in the same row, holding down the last actuation for at least X seconds.
“Tap PEM key+1 tap of SEM pointer 110 at: E110, W 111, N112, E 113 or S114” means to tap the appropriate PEM key 101 or 102 corresponding the section of the table in which the row containing the data string is located in the table the number of times indicated in the cell in the column labeled “# taps on PEM or TEM keys” that is in the same row, and then tap one of the four actuation positions of the SEM pointer, E110, W 111, N112, E 113 or S114, once.
“Tap PEM key+1 tap of SEM pointer 110 at: E110, W 111, N112, E 113 or S114” means to tap the appropriate PEM key 101 or 102 corresponding the section of the table in which the row containing the data string is located in the table the number of times indicated in the cell in the column labeled “# taps on PEM or TEM keys” that is in the same row, then tap one of the four actuation positions of the SEM pointer 110, W 111, N112, E 113 or S114 once, holding down the last actuation at least X seconds.
“Tap PEM key+2 taps of SEM pointer 110 at: E110, W 111, N112, E 113 or S114” means to tap the appropriate PEM key 101 or 102 corresponding the section of the table in which the row containing the data string is located in the table the number of times indicated in the cell in the column labeled “# taps on PEM or TEM keys” that is in the same row, and then tap one of the four actuation positions of the SEM pointer, E110, W 111, N112, E 113 or S114, twice.

After executing the instructions corresponding to the particular cell of Table 1 in FIG. 3 using keyboard 100, the data string in that cell will be entered into the typable device of which keyboard 100 is a part. The following examples will make clear how to read Table 1. For example, to enter ‘q’ the user presses (or taps) key 101 once; to enter ‘Q’ the user presses the key 101 once, holding it down for >X seconds; to enter ‘k’ the user taps PEM key 102 twice and N 112 once (tapping TEM key 115 once immediately after enters ‘K’); to enter the data string—'s (apostrophe ‘s’), the user taps the right key 102 twice, then taps actuation position N 112 twice; to enter the character string ‘hello’, the user taps the right key 102 four times, then taps actuation position S 114 twice; and to enter ‘4 ’ the user actuates the left key 101 once, then the actuation position E 113 once.

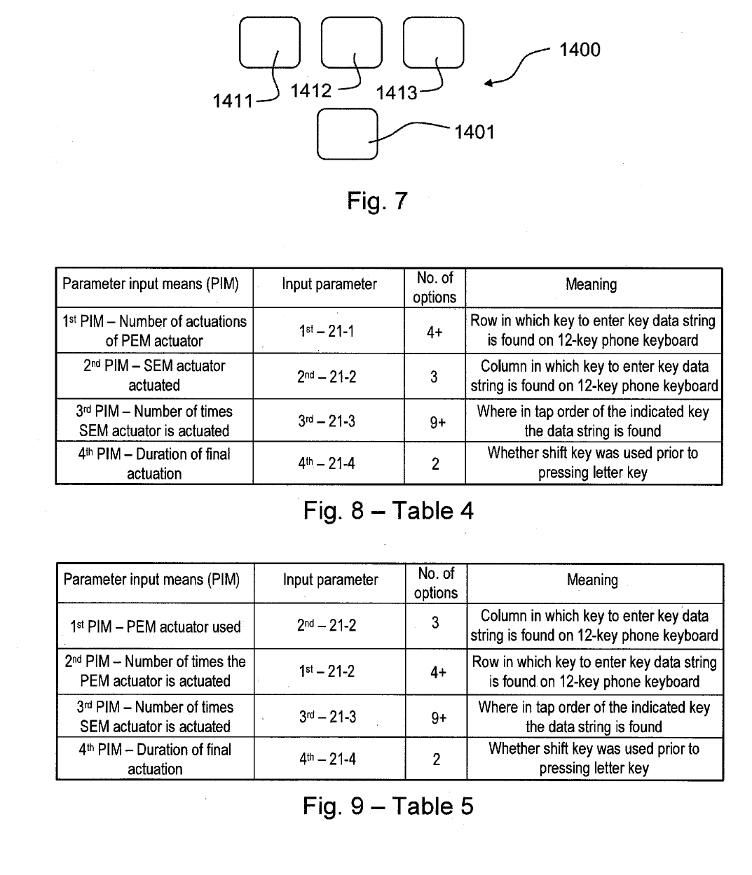

For another example, let us examine how the method is implemented enable a compact keyboard such as the keyboard 1400 having four keys shown in FIG. 7 to emulate the 12-key multi-tap keyboard 2100 shown in FIG. 12. Keyboard 1400 comprises three keys, left key 1411, middle key 1412 and right key 1413 aligned above key 1401; any arrangement of at least four keys will work. 12-key multi-tap keyboards are commonly used for alphanumeric text messaging from cellular phones and are therefore familiar to many. First, as shown in FIG. 12, four input parameters for the emulated keyboard 2100 are defined: Row-IP is the first input parameter 21-1; Column-IP is the second input parameter 21-2; Tap order-IP is the third input parameter 21-3; and Shift-IP is the fourth input parameter 21-4.

Next, four parameter input means for keyboard 1400 are defined and are matched up with the four input parameters for 12-key keyboard 2100. The actuators are first separated into two groups, a first PEM group consisting of actuator 1401 and a second SEM group consisting of actuators 1411, 1412, and 1413. The first parameter input mechanism is PEM number-PIM and serves to enter the first input parameter 21-1. If PEM key 1401 is actuated once, the first and top row of the 12-key phone keypad is indicated as the row in which the key to enter a desired data string is located; if it is actuated twice, the second row is indicated; if it is actuated thrice, the third row is indicated; and if it is actuated four times, the fourth and bottom row is indicated. The second parameter input mechanism is SEM key choice-PIM and serves to enter the second input parameter 21-2. Actuating SEM key 1411 indicates that the key of the 12-key keypad 2100 used to type the desired data string is in the first column of keys, actuating SEM key 1412 indicates it is in the second column, and actuating SEM key 1413 indicates it is in the third column. The third parameter input mechanism is SEM number-PIM and serves to enter input parameter 21-3. The number of times the particular SEM key (1411, 1412, 1413) is actuated indicates the desired data string's position in the tap order of the key indicated by the first two input parameters, and is the same as the number of times the indicated key is tapped to enter that data string (e.g., tapping the indicated SEM key once indicates the first data string in the tap order, twice the second, and so on). The fourth IP is last last hold-PIM and serves to enter the fourth input parameter 21-4; holding the last actuation down for longer that X seconds indicates use of the shift key. Table 4 in FIG. 8 shows the input parameter-parameter input mechanism assignments.

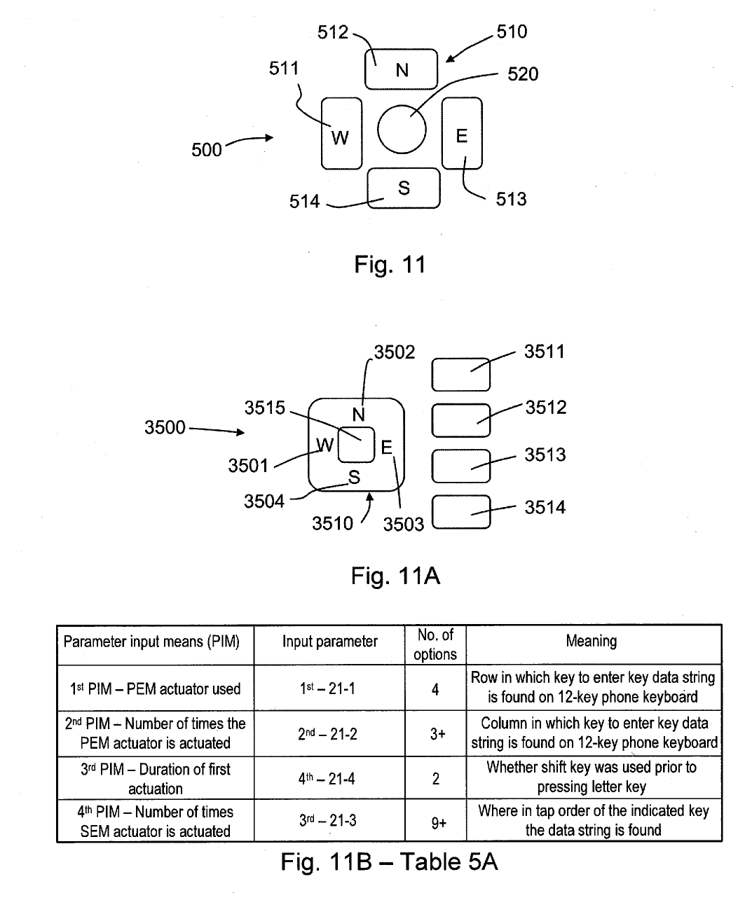

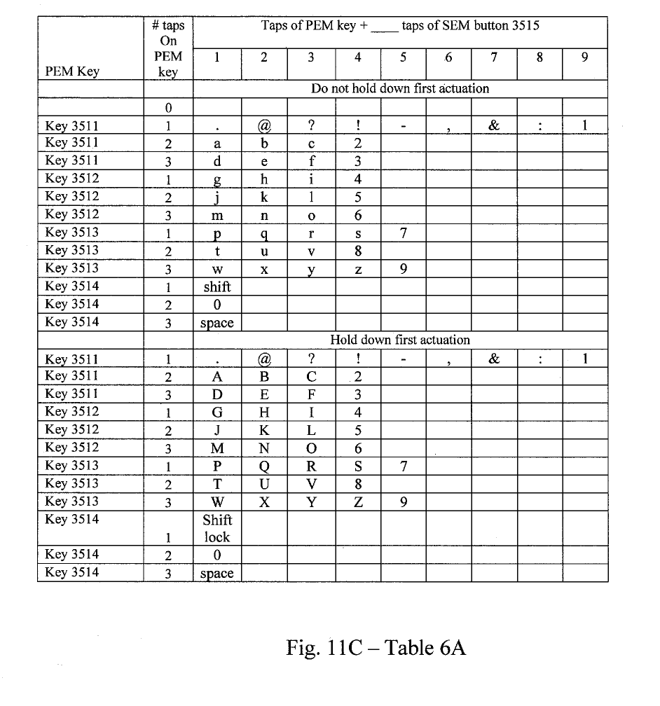

The keyboard setup (which will later be referred to as “Version 1”) created by the parameter input mechanism-input parameter assignments shown in Table 4 in FIG. 8 for keyboard 1400 is shown in Table 3 in FIG. 11. One advantage of this keyboard setup for keyboard 1400 is that after the row is indicated by actuation of the PEM key 1401, the left SEM key 1411 is operated just like the corresponding left key in the indicated row of the 12-key phone keypad would be operated to enter the particular data string, the middle SEM key 1412 is operated just like the corresponding middle key in the indicated row of the 12-key phone keypad would be operated to enter the particular data string, and the right SEM key 1413 is operated just like the corresponding right key in the indicated row of the 12-key phone keypad would be operated to enter the particular data string

The operation of the keyboard 1400, using Table 3 in FIG. 11 as a guide is as follows. Actuation sequences start with one to four actuations of the PEM key 1401 to indicate the row in which the key to enter a desired data string is located on the 12-key phone keyboard 2200. The SEM key 1411, 1412 or 1413 used next in the actuation sequence indicates the column in which the key to enter the desired data string is located on the 12-key phone keyboard 2100, and the number of times it is actuated indicates the data string's position in the tap order of data strings entered using that key. The last actuation of the actuation sequence is either held down to indicate that the shift key is used on keyboard 2100 to type the data string, or not. Reading Table 3, the location of the cell in which a data string is located indicates the number of times the PEM actuator 1401 is actuated, which SEM actuator 1411, 1412 or 1413 is used, how many times the SEM actuator is actuated, and whether to hold down the last actuation to indicate the shift key is used to enter the data string. The empty cells can be used for other data strings into the typable device keyboard 1400 is part of. The actuation sequence for entering a data string is indicated by its position in the Table 3: the PEM key 1401 is actuated the number of times indicated by the number in the second column that is in the same row as the data string, the SEM key actuated is indicated by the heading of the section of columns in which the cell containing the data string is located and the number of actuations of that SEM key is indicated by the number in the row just above the row containing the label “Do not hold down last actuation” that is also in the same column as the data string, and whether the last actuation is held or not is indicated by whether the data string is above or below the row containing the label “Hold down last actuation”, with those below being entered by an actuation sequence in which the last actuation is held down for >X seconds. Examples will help clarify this: to enter ‘B’, the PEM 1401 is actuated once and then the middle key 1412 is actuated twice, with the second actuation held down; to enter ‘9 ’, the PEM key 1401 is actuated three times and then the right key 1413 is actuated 5 times; to enter ‘@’ the PEM key 1401 is actuated once and the left SEM key 1411 is actuated twice; and to enter ‘0 ’ the PEM key 1401 is actuated four times and the middle SEM key 1412 is actuated once.

The following example illustrates how the keyboard setup for keyboard 1400 will change with alterations in the PIM-IP assignments and changes to parameter input mechanism definitions. The four keys comprising keyboard 1400 are again separated into two groups. However, this time keys 1411, 1412 and 1413 are in the PEM group and key 1401 is in the SEM group. The same defined input parameters are used. Instead of the PIM-IP assignments shown in Table 4 in FIG. 8, the PIM-IP assignments shown in Table 5 in FIG. 9 are used to create a keyboard setup that allows keyboard 1400 to emulate 12-key keyboard 2100. The first parameter input mechanism is PEM key choice-PIM and serves to enter second input parameter 21-2 (Column-IP as defined in FIG. 6). Using the three PEM keys 1411, 1412 and 1413 to indicate the column in which the key to enter a particular data string is located using a 12-key phone keypad 2100 is appropriate because the physical arrangement of the three PEM keys mimics the physical arrangement of columns of keys on the keyboard 2100, and so pressing left key 1411 indicates the left column, pressing middle key 1412 indicates the middle column, and pressing the right key 1413 indicates the right column thus making the keyboard 1400 more intuitive to use. Actuating PEM key 1411 indicates that the key of the 12-key keypad 2100 used to type the desired data string is in the first column of keys, actuating PEM key 1412 indicates it is in the second column, and actuating PEM key 1413 indicates it is in the third column. The second parameter input mechanism is PEM number-PIM and serves to enter first input parameter 21-1, Row-IP. If PEM key used is actuated once, the first and top row of the 12-key phone keypad is indicated as the row in which the key to enter a desired data string is located; if it is actuated twice, the second row is indicated; if it is actuated thrice, the third row is indicated; and if it is actuated four times, the fourth and bottom row is indicated. The third parameter input mechanism is SEM number-PIM and serves to enter input parameter 21-3, tap order-PIM. The number of times the particular SEM key 1401 is actuated indicates the desired data string's position in the tap order of the key indicated by the first two input parameters, and is the same as the number of times the indicated key is tapped to enter that data string. The fourth IP is last last hold-PIM and serves to enter the fourth input parameter 21-4, shift-IP; holding the last actuation down for longer that X seconds indicates use of the shift key.

The keyboard setup shown in Table 6 in FIG. 10 is the result of definitions of parameter input means and their assignments to input parameters (and will be referred to later as “Version 2”). Only the data strings that can be entered using keyboard 2100 are in Table 6 (this is just an example; other 12-key phone keypads may enter a different set of data strings, or enter the same ones differently. Empty cells in Table 6 indicate actuation sequences available for entering data strings even without increasing the number of PIM options beyond what is needed for entering keyboard 2100's data string set. Table 6 indicates the actuation sequences to enter a data string as follows: the actuation sequence to enter a data string is indicated by its location in the table, and the number in the second column corresponding to the data string's row is the number of times the PEM key indicated in the first column for that row is actuated, and the number in the data string's column just above the row containing the label “Do not hold down last actuation” is the number of times SEM key 1401 is actuated, and the last actuation in the actuation sequences for the data strings below the row containing the label “Hold down last actuation” are held down, while those for data strings above that row are not. To enter ‘@’ PEM key 1411 is actuated once and SEM key 1401 is actuated twice; to enter ‘1 ’ PEM key 1411 is pressed once and SEM key 1401 is pressed nine times; to enter ‘y’ PEM key 1413 is tapped three times and SEM key 1401 is tapped three times; and to enter T PEM key 1412 is tapped twice and SEM key 1401 is tapped once.

The keyboards 500 in FIG. 11 and keyboard 100 in FIG. 12 each comprise five actuators. These keyboards can be used to emulate 12-key phone keypads such as keyboard 2100 in the same way as keyboard 1400. To do so, four of the five actuators of each need to be selected and segregated into two groups, one having three members, one having one. The PIM-IP definitions and assignments in Tables 4 and 5 can then be used, and the keyboard setups for the keyboards 500 and 100 will be the same as in Tables 3 and 6, depending upon the PIM-IP assignments and definitions used. The fifth actuator in each can be put in the TEM group, and can be used as part of actuation sequences after the SEM actuator, or alone without being preceded in the actuation sequence by PEM and SEM actuations; if the TEM alone is used to enter spaces the efficiency of the keyboard is increased significantly as spaces are the most common data strings in text. Keyboard 500 comprises a 4-way navigation device consisting of four keys, W key 511, N key 512, E key 513 and S key 514, surrounding a central key 520. Substituting center key 520 for actuator 1401 and substituting W key 511, N key 512 and E key 513 for actuators 1411, 1412 and 1413 respectively, the keyboard setups in Tables 3 and 6 can be used with keyboard 500. Alternately, S key 514 can be substituted for actuator 1401.

FIG. 11A is a schematic illustration of another keyboard 3500 emulating a 12-key phone keypad 2100. Keyboard 3500 is similar to the arrangement of actuators on some electronic devices such as digital cameras. Keyboard 3500 comprises four keys aligned vertically, a first 3511, second 3512, third 3513 and fourth 3514 keys, to the right of a 4-way navigation device or controller 3510 having four actuation positions at the cardinal points of the compass, west (W) actuation position 3501, north (N) actuation position 3502, east (E) actuation position 3503 and south (S) actuation position 3504, with a button 3515 in its center. Like with all 4-way controllers or pointing rings, controller 3510 can be replaced by a set of four similarly located keys. The emulating and emulated keyboards are chosen as have the keys to be emulated (all of the keys of the 12-key keypad).

The next step is to define the input parameters and parameter input mechanisms that will be used. Four input parameters are needed, and the four that will be used are row-IP (21-1), column-IP (21-2), shift-IP (21-4) and tap order-IP (21-3). Four parameter input mechanisms are needed. Only five actuators of keyboard 3500 will be used to enter the key data strings (those text characters that can be entered using all keys of the 12-key phone keypad when operating in text entry mode), the four keys 3511-3514 and the center button 3515, which will be divided into two groups, a first group consisting of keys 3511, 3512, 3513 and 3514, and a second group consisting of button 3515. Other actuators may be set up for convenience, to improve text entry efficiency or to provide addition text entry functionality. Which of the four keys 3511, 3512, 3513, and 3514 in the first group is used will serve as a first parameter input mechanism, key choice-PIM. The number of times the key in the first group used is actuated will serve as a second parameter input mechanism, number-PIM. Whether the first actuation of the actuation sequence is held or not will serve as a third parameter input means, first hold-PIM. And the number of actuations of the button 3515 will serve as a fourth parameter input means, also number-PIM.

The next step is to assign parameter input means to enter input parameters. Since there are four rows of keys in the phone keypad 2100 and four keys in the first group, which of the keys in the first group is used (key choice-PIM) will serve to enter the first input parameter 21-1, row-IP. Assigning these four keys to enter the row-IP is appropriate as well because the four keys 3511, 3512, 3513 and 3514 are arranged vertically and mimic the arrangement of the rows, and the key used will correspond physically to the position of the row it is indicating, making the emulating keyboard 3500 more intuitive to use. The number of times a key in the first group is actuated (number-PIM) will serve to enter the second input parameter 21-2 (column-IP) since it can enter three or more values and there are only three columns. Whether the first actuation in an actuation sequence is held down for at least some predetermined time or not (first hold-PIM) can have two values and will serve to enter the fourth input parameter 21-4 (shift-IP) which also has two values (shift used or not). The fourth parameter input means using button 3515 (number-PIM) can have any number of values and will serve to enter the third input parameter 21-3 (tap order-IP) which needs to have at least nine values to enter the nine text characters assigned to the 1-key of the 12-key keypad 2100.

These assignments and definitions are shown in Table 5A in FIG. 11B. Note that operating the shift key has no effect upon the punctuation and number data strings when operating the version of the phone keyboard 2100 and so there are two actuation sequences for each of these, one in which the first actuation is held and one in which it is not. Obviously, the latter are easier and faster to execute. Also, the space and ‘0 ’ data strings are the only data strings entered using their respective keys of the phone keypad 2100, and if none of the other available actuation sequences indicated by the empty table cells sharing the same rows with the space and ‘0 ’ data strings are used, it is possible to skip the SEM key 1401 actuation since it is redundant (i.e., there is only one data string assigned to the key identified by the PEM actuation and so the data string to be entered is already exactly specified).

The keyboard setup that results from the assignments and definitions in Table 5A are expressed in the form of Table 6A in FIG. 11C. There are now four PEM keys actuated one to three times to specify exactly the key used on the emulated keyboard to enter a data string. Table 6A serves as a guide to actuation sequences: first operate the PEM key indicated in the first cell the number of times indicated in the second cell of the row in which the cell holding a data string is located, holding the first actuation down or not holding it down as indicated by the label of the sub-section of rows in which that cell is located, then operate the SEM button 3515 the number of times indicated in the first cell of the column in which the cell containing the data string is located. For example, to enter ‘L’ press the PEM key 3512 twice, holding down the first actuation of the actuation sequence for at least some predetermined time, then press the SEM button 3515 three times.

For improved efficiency in entering text characters, the S actuation position 3504 can be used to enter spaces. The W actuation position can be used for backspace delete. The N 3502 and E 3503 actuation positions can be set up to be used for other text entry related functions. Alternatively, the 4-way navigation device 3510 can be removed from the keyboard 3500, leaving only the five actuators used for text entry and for emulating the 12-key phone keypad 2100, first key 3511, second key 3512, third key 3513, fourth key 3514 and button 3515.

FIG. 12 shows electronic device 133 comprising a display 132, and a keyboard 130 comprising a touch sensitive click wheel 120 (such as that found on the Apple iPod®) with four defined actuation positions, West actuation position 121, North actuation position 122, East actuation position 123 and South actuation position 124 at their respective quadrants of the click wheel 120, and a center button 125 inside the click wheel 120. Substituting button 125 for actuator 1401 and substituting W actuation position 121, N actuation position 122, and E actuation position 123 for actuators 1411, 1412 and 1413 respectively, the keyboard setups in Tables 3 and 6 can be used with keyboard 120. Alternately, S actuation position 124 can be substituted for actuator 1401. Note that click wheel 120 with four defined actuation positions is more or less equivalent in operation to 4-way navigation devices 110 and 510 in FIG. 1 and FIG. 11 respectively.

FIG. 13 shows alternative input parameters for a QWERTY keyboard from those in FIG. 20. The first input parameter 20-1B is the row in which the key to enter a particular data string is located on the QWERTY keyboard 2200. The second input parameter 20-2B is which of the five groups or sections of rows the key is in, with the first section consists of the first two keys in each row starting from the left, the second section consists of the next two keys in each row, and so on. The third input parameter 20-3B indicates whether the key is the first and left key in the section or the second and right key. The fourth input parameter 20-4B indicates whether the shift key is utilized to enter the data string. Only the forty keys in the five sections will be emulated.

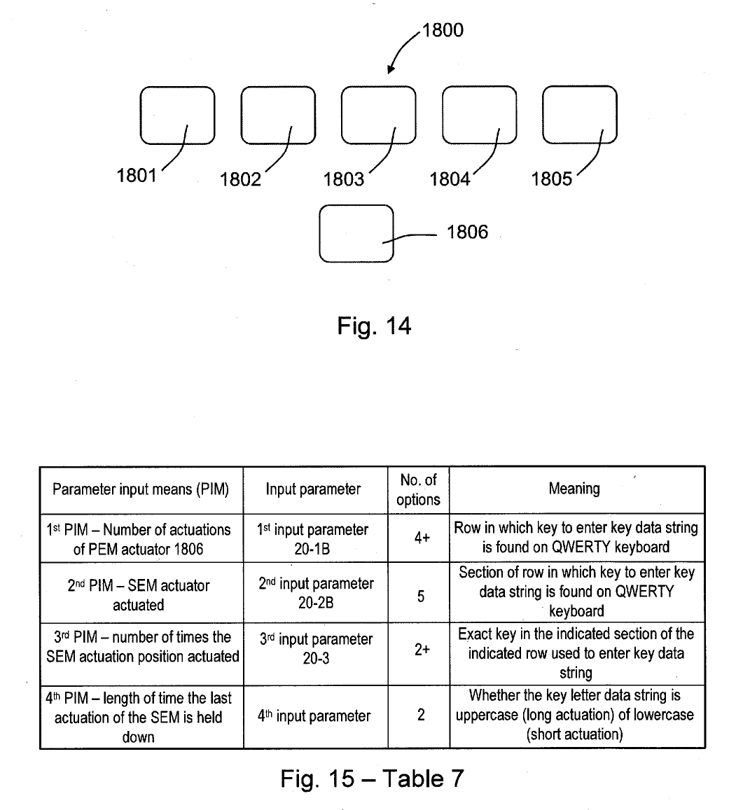

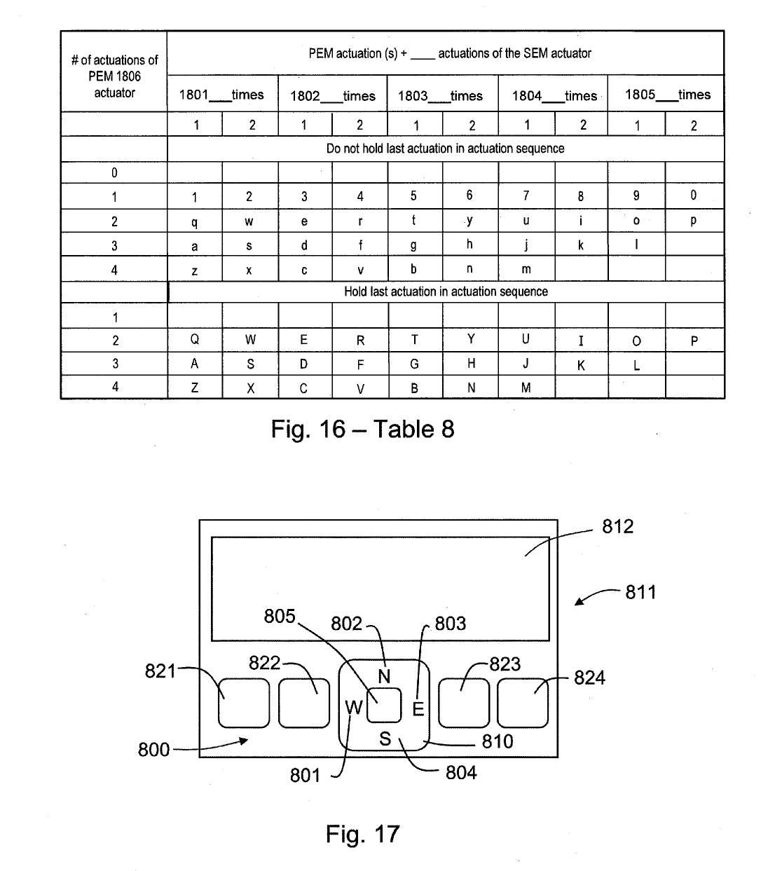

Keyboard 1800 shown in FIG. 14 comprising six keys, five keys 1801-1805 linearly aligned above the sixth key 1806. To create the data string entry rules for keyboard 800 so that it will emulate QWERTY keyboard 2200, the keys are divided into two groups, the PEM consisting of key 1806 and the SEM consisting of the other five keys 1801-1805. The parameter input means are as follows: PEM number-PIM serves to enter the first input parameter 20-1B wherein one actuation indicates the first row, two actuations indicates the second row, and so on; SEM key choice-PIM serves to enter the second input parameter 20-2B (use of key 1801 indicates the first section, use of key 1802 indicates the second section, use of key 1803 indicates the third section, use of key 1804 indicates the fourth section, and use of key 1805 indicates the fifth section); and SEM number-IP serves to enter the third input parameter 20-3B (one actuation indicates the first key, two indicates the second key); and last hold-PIM serves to enter the fourth input parameter 20-4B, wherein holding the last actuation down indicates that the shift key is used to type the data string. The PIM-IP assignments are shown in Table 7 in FIG. 15. Table 8 in FIG. 16 contains the keyboard setup for keyboard 1800 that results from the defined parameter input mechanisms and input parameters. To enter a data string using Table 18b as a guide, the actuation sequence is as follows: first actuate the PEM key 1806 the number of times indicated in the first column for the row in which the cell containing the data string is located, then actuate the SEM actuator under which the data string's cell is located the number of times indicated by the number in the row just above the “Do not hold last actuation . . . ” label and also in the same column as data string's cell is located, holding it or not holding the last actuation as indicated by the heading of the subsection of the table in which that data string's cell is located. For example, to enter ‘m’, actuate PEM key 1806 four times and then SEM actuator 1804 once; and to enter ‘R’, actuate PEM actuator 1806 twice and SEM actuator 1802 twice, holding the last actuation. To improve the keyboard setup for keyboard 1800 for text entry mode, it may be advisable to move the numbers to the bottom row of each section requiring four actuations of the PEM actuator, and moving the letter data string rows up one row each. This will make it slightly harder to learn to use the keyboard 1800, but a user needs only to remember to pretend that the number row is below the letter rows in the keyboard being emulated.

The second 20-2B, third 20-3B and fourth 20-4B input parameters illustrated for QWERTY keyboard 220 in FIG. 13 are the input parameters used by a Blackberry SureType 20-key multi-tap keyboard which consists of four rows of five keys each. It will be obvious from the preceding and from examples elsewhere herein how to apply the disclosed method to enable keyboard 1800 to emulate a Blackberry SureType keyboard, such as by defining the PEM as keys 1801-1805 and the SEM as key 1806, and letting the choice of key in the PEM (1801-1805) that is actuated enter the column-IP, the number of times the PEM key chosen is actuated enter the row-IP, the number of actuations of the SEM key 1806 enter the tap order-IP, and whether the first (or last) actuation is held for at least some predetermined length of time entering the shift-IP into a typable device.

In an alternate embodiment, there are only five keys 1801-1805 and only one group of keys, and the key actuated indicates the section of the row and the number of times the key is actuated indicates the row in which the key to enter a particular data string is located on QWERTY keyboard 2200 (one actuation indicates the first row, two the second row, etc.), and the duration of the last actuation sequence indicates which of the two keys in the indicated section of the row is used to enter the data string. This embodiment cannot type capital letters because it only has three parameter input mechanisms.

FIG. 17 shows electronic device 811 comprising a display 812 and keyboard 800 comprising a pointing ring or 4-way navigation device 810 having four defined actuation positions, West actuation position 801, North actuation position 802, East actuation position 803 and South actuation position 804 at their respective quadrants of the pointing ring 810, a button 806 in the middle of the pointing ring 810, and four horizontally aligned keys with a first key 821 and a second key 822 positioned to the left of pointing ring 810, and a third key 823 and fourth key 824 positioned to the right of pointing ring 810. This is the user interface found on Palm Pilots® and many other PDAs. By defining six actuators to substitute for the six actuators of keyboard 1800, the keyboard setup in Table 8 in FIG. 16 can apply to keyboard 800 and it can be used to emulate the QWERTY keyboard 2200 in FIG. 13. In one embodiment, the actuators 821, 822, 802, 823 and 824 are substituted for actuators 1801, 1802, 1803, 1804 and 1805 respectively, and button 806 is substituted for actuator 1806. South actuator 804 can be used to enter spaces, W actuator 801 can be used for backspacing, and E actuator 803 can be used for delete among other things. Any keyboard setup for keyboard 1800 will now work for keyboard 800, including that in Table 8 in FIG. 16. Keyboard setups for keyboard 100 in FIG. 1 will work for keyboard 800 as well since there are fewer actuators in keyboard 100; keys 821 and 824 will not be used for emulation, but can be used for other purposes or not at all in text entry.

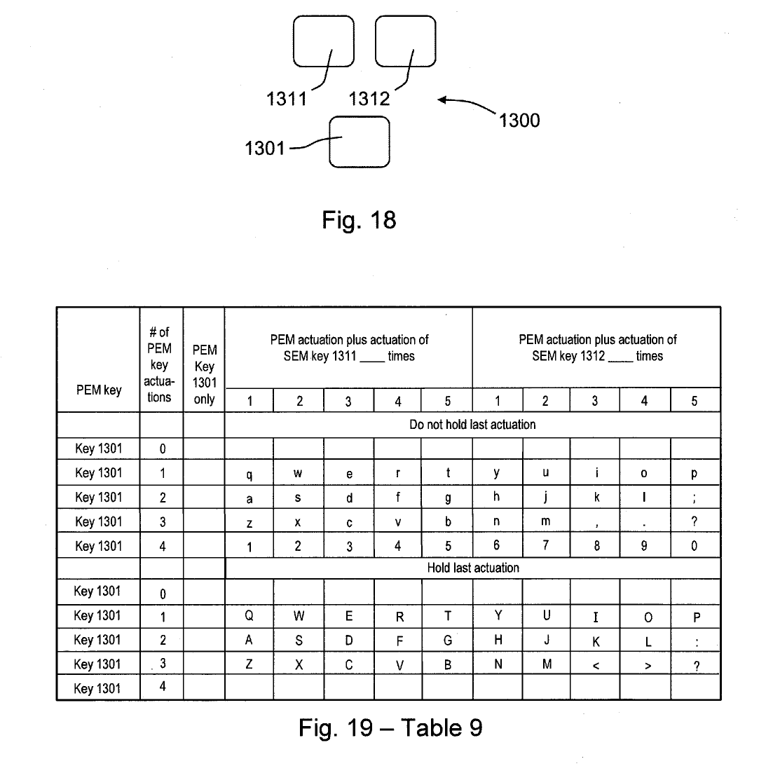

The keyboard 1300 in FIG. 18 has three actuators. The PEM is defined as a first key 1301 and the SEM is defined as a second 1311 and third 1312 keys. The physical arrangement of the keys is the PEM key 1301 centered below the two horizontally aligned SEM keys, but any physical arrangement of the three keys is acceptable. Keyboard 1300 will be used to emulate QWERTY keyboard 2100 in FIG. 2 using the four input parameters shown there. The first PIM is PEM number-PIM which serves to enter input parameter 20-1, with the number of actuations that indicates a given row is its ordinal number. The second PIM is SEM key choice-PIM which serves to enter input parameter 20-2, with the use of key 1311 indicating that the key to enter a given data string is in the left side of the keyboard 2200 and use of key 1312 indicating that it is in the right side. The third PIM is SEM number-PIM which serves to enter input parameter 20-3, with the number of actuations of the SEM actuator used indicating the position of the key in the indicated section of the row counting from the left. The fourth PIM is last hold-PIM which serves to enter input parameter 20-4, with holding of the last actuation indicating that the shift key is used to enter a particular data string. Table 9 in FIG. 19 shows the keyboard setup under which keyboard 1300 emulates forty keys of a QWERTY keyboard that results from the preceding definitions of PIMs and IPs and the PIM-IP assignments. The table indicates actuation sequences in the same way as tables already described. The data strings in Table 9 are the data strings that can be entered using the forty keys of the QWERTY keyboard 2100 that are indicated in FIG. 2; all empty cells indicate unused actuation sequences. For example, to enter ‘k’ the user actuates PEM key 1301 twice and right SEM key 1312 three times, to enter ‘q’ the user actuates PEM key 1301 once and first SEM key 1311 once, to enter ‘0 ’ the user actuates the PEM key 1301 four times and the right key 1312 five times and to enter ‘S’ the user actuates the PEM key 1301 twice and the left SEM key 1311 twice.

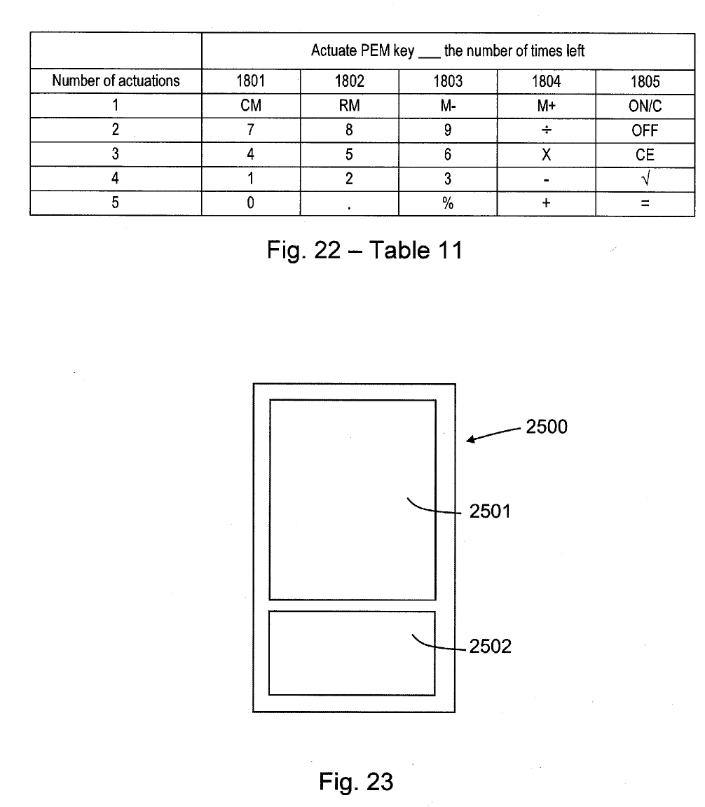

FIG. 20 shows one set of input parameters for emulating a calculator keyboard 2300 having five rows of five keys each. The first input parameter 23-1 indicates the row in which the key to enter the desired data string is found and the second input parameter 23-2 indicates the column of keys (or which key in the row) in which the key to enter the desired data string is found. The keyboard that will be used to emulate the calculator is keyboard 1800 in FIG. 14. Only the five keys 1801-1805 will be used, and all will be in the PEM group, with the PEM comprising the two PIMs necessary to uniquely identify every data string that can be entered using keyboard 2300. The first parameter input means will be which of the five keys 1801-1805 is used and will serve to enter the second input parameter 23-2, with use of the first key 1801 indicating the first column (in order from the left), use of the second key 1802 indicating the second column, use of the third key 1803 indicating the third column, use of the fourth key 1804 indicating the fourth column, and use of the fifth key 1805 indicating the fifth column. The second input parameter will be the number of actuations of the key used which will serve to enter the first input parameter 23-1, and one actuation will indicate the first row starting from the top, two the second row, three the third row, four the fourth row and five the fifth row. Table 10 in FIG. 21 shows these PIM-IP assignments. The keyboard setup corresponding to the PIM-IP definitions and assignments in Table 10 is expressed in Table 11 in FIG. 22. Any keyboard comprising at least five actuators can operate according to the keyboard setup in Table 11, either as its sole operating mode or as a separate ‘calculator operating mode.’

The method disclosed here for enabling a compact keyboard to emulate a keyboard with many more keys can be extended to keyboards for other languages. Some languages consist of an alphabet but use diacritics as well (e.g., Arabic, German). The disclosed method can easily be used for those languages as well by defining an input parameter or parameters for entering diacritics (often done using a modifier key using full-sized keyboards) and defining appropriate parameter input means for each. Once the PIMs are assigned to enter the IPs, the keyboard setup for those keyboards will be determined. Some of those languages have keyboards that can be emulated using one of the methods described above or another of the many obvious methods possible. Often these keyboards allow users to enter both English (for the Internet) and their own language, and an embodiment of the disclosed keyboards may need a mechanism for switching between languages. Adding diacritics can be done by actuating a TEM actuator some number of times after executing the actuation sequence to enter the letter to which the diacritic will be added. The TEM can consist of one actuator or can consist of more than one actuator. Or letters with diacritics can simply be treated as data strings that can be entered using an actuation sequence consisting of a PEM and SEM actuation only. In some languages, like Arabic, the letters may have a different form depending upon the location of the letter in a word. Keyboards operating according to operating rules developed using the disclosed method may automatically convert the letter to the correct form or the different forms may be separate data strings, each entered by executing its own unique actuation sequence. Non-English languages may have equivalents of uppercase and lowercase that can be dealt with as described above or in another way.

Note that in a sense, the designer of the keyboard setup for the emulating keyboard creates a combined real and virtual version of the emulated keyboard in which the emulated keyboard is expanded by the addition of further rows of virtual keys and/or additional virtual keys in each row, and even additional layers of virtual keys, with each virtual key being used to enter additional data strings above and beyond the key data strings entered using the real keys of the emulated keyboard and which are being emulated by the disclosed keyboard. Increasing the number of PIMs utilized in entering data strings can increase the number of dimensions of the virtual emulated keyboard while increasing the number of options for the PIMs-IPs already utilized increases the size of existing dimensions. For example, increasing the options available and used for the Row-IP and Column-IP (such as by making available higher numbers beyond the number of actual rows and columns of the emulated keyboard) increases the number rows and columns respectively of the virtual keyboard conceptualized from the keyboard setup. Increasing the Position left-IP and Position right-IP and the associated PIMs increases the length of the rows of the virtual keyboard. Increasing options utilized for the Tap order-IP and associated PIM increases the number of data strings assigned to each key of the virtual keyboard. Increasing the number of options available and used for Shift-IP and the associated PIM increases the number of levels of virtual levels of keys in the virtual keyboard (any keyboard that allows use of a modifier key already has at least one virtual level of keys). In some cases it may be desirable to enable the emulating keyboard to emulate actual rows of the emulated keyboard that do not contain the key data strings, such as the function key row of full-size computer keyboards, but to do so out of its actual order. One such embodiment was described above with reference to Table 1 in FIG. 3 wherein the number key row is emulated, but out of order, with it being the fourth row of the virtual keyboard instead of the first row as it actually is Small changes such as this can still exploit a user's familiarity with the emulated keyboard while improving the emulating keyboard's efficiency and requiring only a small deviation from the simple rules. In some embodiments of keyboards emulating a QWERTY keyboard, it may be desirable to have a text entry mode which operates under a keyboard setup in Table 1 where the number row has been relegated to fourth in the row order after the three letter rows (the virtual keyboard that reflects the actuation sequences would have the numbers in a fourth virtual row) and a number entry mode where the keyboard setup reflects the physical layout of the emulated keyboard.

As can be seen, the method of creating rules of operation for a compact keyboard that exploit familiarity with common less-compact keyboard also creates a method of entering data string that enables a very compact keyboard to enter huge numbers of data strings in a highly structured way. This highly structured input method is conducive to the display of hints, such as the data strings that will be entered if the SEM or TEM is actuated some number of times. The structure also makes it easy for designers to organize non-key data strings in a way that makes remembering how to enter them easier.

The user interface for a typable device will often comprise an emulating keyboard plus additional user interface controls such as additional actuators, keys, buttons, scrolling, or pointing mechanisms not part of the emulating keyboard. Some uses for these additional actuators are described above. They can be used to expand the ‘virtual keyboard’ embodied in the keyboard setup for the emulating keyboard beyond that portion of the keyboard setup that emulates another keyboard, and allow the entry of data strings either not in that portion of the emulated keyboard that was emulated or that the emulated keyboard cannot enter into a typable device using a single key either in combination with a modifier key or not. A number of the emulating keyboards embodiments disclosed here use the last hold-PIM to indicate the use of the shift key in entering a data string, and do not use the TEM actuator, if there is one, in the actuation sequences for key data strings. The TEM key choice-PIM or TEM number-PIM can be used for that purpose instead of the using the last hold-PIM and to indicate use of not only the shift key but also the Ctrl, Alt and other modifier keys; for example, no TEM actuation after the PEM and SEM actuations in the actuation sequence can indicate that no modifier key was used, one actuation can indicate use of the shift key, two actuations can indicate use of the Ctrl key, three actuations can indicate use of the Alt keys, and so on.

The keyboards described above operate according to rules created using the method for enabling a compact keyboard to emulate another familiar keyboard having many more keys. These rules of operation allow the emulated keyboard to serve as a mnemonic for entry of at least the key data strings.

Keyboards and typable devices comprising them that incorporate operating software which enables them to operate according to the rules of operation created using this method which enable the keyboard to emulate another keyboard, operate The method for creating the rules for operating a compact keyboard to emulate a less compact keyboard results in a method for entering data strings into a typable device using a compact keyboard comprising one or more actuators which provide at least two parameter input means, wherein each parameter input means has at least two states or options, and each parameter input means inputs, communicates or selects one of several input parameters that together provide all the information required to indicate how a particular data string is entered using a second keyboard being emulated. In other words, the method involves using the actuators of the disclosed keyboard to select, input, or communicate to a processing unit of some sort everything that is needed to specify exactly how to enter a specific data string using another keyboard. For example, if ‘k’ is entered using the third key (3^{rd} input parameter) in the right half (2^{nd} input parameter) of the second letter row (1^{st} input parameter) of a full-sized QWERTY keyboard, then the method consists of using the actuators of the disclosed keyboard to communicate these three parameters, such as by entering the first parameter to indicate the row in which the key to type is located on the QWERTY keyboard by means of one or more actuations of a first actuator (first parameter input means), entering the second parameter to indicate the section of that row in which the key is located by selecting and actuating one of a plurality of actuators in a first group of actuators (second parameter input means) to use to enter the first input parameter, and entering the third parameter to indicate where in that section of that row the key to enter ‘k’ is located by selecting and actuating one of a plurality of actuators in a second group of actuators (third parameter input means).

The use of this method to enter some set of data strings using a disclosed keyboard involves using the parameter input means of the disclosed keyboard to enter the input parameters required to indicate how a data string in that set is entered using a disclosed keyboard (i.e., executing an actuation sequence comprising actuation of a series of parameter input means), storing the input parameters in a buffer or tabulating them until the actuation sequence is completed (completion can be indicated by the several methods already described), then interpreting the set of input parameters entered as the entering of said data string in that set and generating the appropriate signal or code.

FIG. 23 shows an electronic device 2500 comprising a display 2501 and a keyboard 2502. The electronic device 2500 can be a portable computer, PDA, cell phone, calculator, camera, electronic game, MP3 player, DVD player, GPS device, tablet computer, or any other electronic device comprising a display and a keyboard. The display 2501 can be of any type, and the keyboard 2502 can be any of the keyboards described herein, and any other keyboard designed and built according to the principles described or illustrated herein.

The devices incorporating the disclosed keyboards may have visual aids to help the user remember which actuators to engage to enter a particular data string, such as that just described. These may be images on the display which aid the user in remembering the proper actuation sequence required to enter a specific letter. For example, when in text mode, after the end of an actuation sequence or before one has been started, an image showing the primary subgroups, in order, assigned to the PEM actuators could be displayed somewhere on the display screen, including as a watermark-type image ‘behind’ the application-related image (e.g., address book, memo, calendar, etc.). Then, after the actuation sequence is started by actuation of a specific PEM actuator, the displayed keyboard-related image could change to show all or some of the letters and other data strings in the subgroups of that PEM actuator. Other types of visual queues might be used. If the letters are not in the exact order of the full-size keyboard being emulated (such as QWERTY), then the displayed image might convey this information simply by displaying the changed order, or by one of the approaches described above for use with labels. There are obviously many ways this text-entry aid could be reduced to practice. Also, there may be labels on the disclosed keyboard.

Unless otherwise defined, all technical terms used herein have the same meaning as commonly understood by one of ordinary skill in the art to which this invention belongs. All publications, patent applications, patents, and other references mentioned herein are incorporated by reference in their entirety. In the case of conflict, the present specification, including definitions will control. In addition, the particular embodiments discussed above are illustrative only and not intended to be limiting.

The foregoing description of the invention has been presented describing certain operable and preferred embodiments. It is not intended that the invention should be so limited since variations and modifications thereof will be obvious to those skilled in the art, all of which are within the spirit and scope of the invention. Although the invention has been disclosed in terms of a number of preferred embodiment and variations thereon, it will be understood that numerous additional modifications and variations could be made thereto without departing from the scope of the invention as defined in the following section.

### Emulating Keyboards Operating Under Predictive Text Algorithms

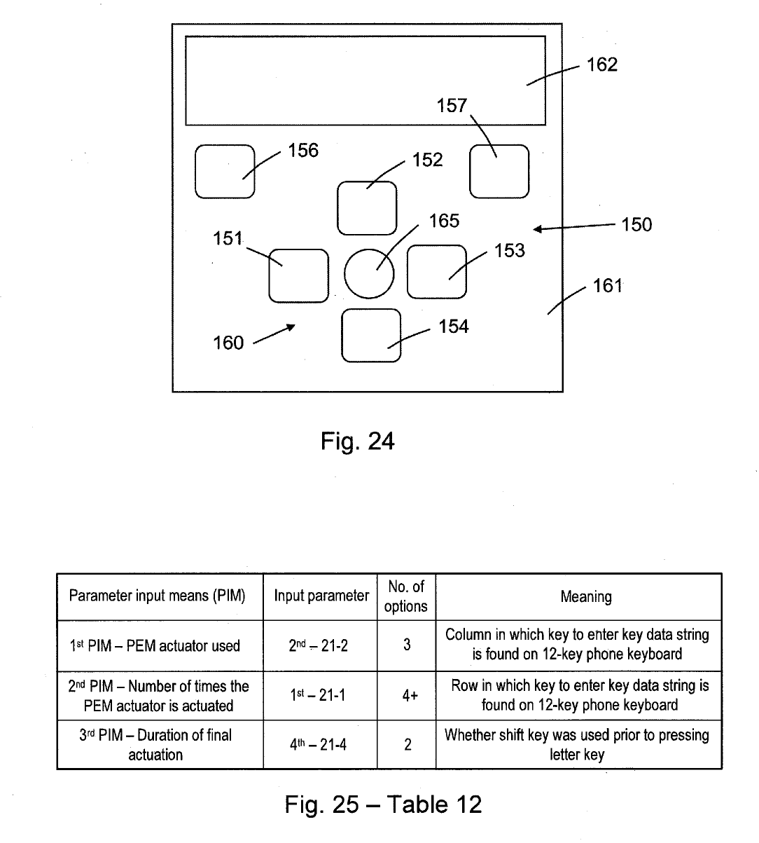

The method disclosed above can be extended to the emulation of familiar keyboards running predictive text (PT) software by compact and ultra-compact keyboards. Electronic device 161 shown in FIG. 24 comprises a display 162, and keyboard 150 comprising center button 165, 4-way navigation device 160 comprising four actuators W 151, N 152, E 153 and S 154 around the center button 165 (W, N, E and S are directions of the compass, assuming N is up so N key 152 is above center button 165, S 154 below, E 153 to the right and W 151 to the left), and two soft-keys, left 156 and right 157. Because Keyboard 150 comprises more than four actuators, it can operate under the keyboard setups for a keyboard having fewer actuators, including the two illustrated in Tables 3 and 6 which enable a keyboard having at least four actuators to emulate a 12-key phone keypad operating in multi-tap mode (keyboard 150 without actuators 156 and 157 is functionally equivalent to keyboards 100, 120 and 500 described above, and any other five actuator keyboard).

As we shall see, keyboard 150 can also be used to emulate a 12-key phone keypad operating in predictive text mode under any predictive text algorithm, including T9, Letterwise, TenGo and iTaps. However, because an emulating keyboard generates the same output as the keyboard it is emulating, a keyboard that is emulating a keyboard running predictive text software has to run the same or similarly functioning predictive text software itself. The 12-key keypad is typically used for text entry with a phone handset, although other keys of the phone text-entry interface are often used for additional text-entry related functions such as delete. The standard text-entry mode on 12-key phone keypads is multi-tap wherein the number of taps of a given key determines the data string entered. Since predictive text algorithms cannot predict the text correctly 100% of the time, keyboards operating under predictive text software must also be able to operate a definitive text entry mode, which for 12-key phone keypads is in multi-tap entry mode. Definitive text entry mode is any mode of operation of a keyboard in which the data string a user intends to enter is known definitively and unambiguously from user operation of the actuators of the keyboard (i.e., no prediction or guessing is necessary). It is also known as unambiguous text entry. Multi-tap mode on 12-key phone keypads is a definitive text entry mode as is the normal mode of operating a full-size QWERTY keyboard.

Two versions of how to create rules of operation for a keyboard having at least four actuators were described with reference to keyboard 1400 in FIG. 7. Version 1 corresponds to the keyboard setup in Table 3 in FIG. 11 while Version 2 corresponds to the keyboard setup in Table 6 in FIG. 10. It was described how to apply these keyboard setups to keyboard 500 which is physically the same as keyboard 150 (in this case by substituting keys 151, 152, 153 and 165 [or 154] for keys 1411, 1412, 1413 and 1401 respectively —Table 6 in FIG. 10 contains the keys used on keyboard 150 in parentheses). The advantage of Version 1 for keyboard 150 is that after indicating the row by tapping the PEM actuator 165 a number of times equivalent to the row's place in the order of rows counting top to bottom, not only does the user operate the appropriate SEM key as he would operate the indicated key of the 12-key phone keypad, but the physical layout of the three SEM actuators mimics that of the keys in the row of the phone keypad—left, middle and right. However, because operation of the appropriate PEM actuator definitively indicates the key of the phone keypad that is used to enter the desired data string, Version 2 has important advantages when it comes to emulating the 12-key phone keypad when it is operating under a predictive text program.

There are two basic kinds of predictive text software algorithms available today: letter-by-letter, such Letterwise from Eatoni Ergonomics Inc., and word-by-word, such as T9® from Nuance Communications, Inc. Devices operating under predictive text software can be said to have predictive text functionality.

### Emulating Keyboards Using Letter-by-Letter Predictive Text Algorithms

Letterwise is an algorithm that is implemented in software for multi-tap and other ambiguous keyboards such as the 12-key phone keypads. Its purpose is to reduce the number of keystrokes required to enter text using a multi-tap keyboard. The Letterwise algorithm tries to predict the letter the user has just entered based upon a statistical table derived from analysis of text corpuses. The table indicates the probability of a particular text character being the next one typed given the text characters already typed, including, according to information available publicly, its position in the word.

The user uses the same keys for text entry when running Letterwise software as when operating in normal, multi-tap mode. In addition, one actuator not used in multi-tap text entry is assigned to be the Next key. On a phone interface incorporating a 12-key keypad, the Next key can be any of the 12 keypad keys not used for text entry or any other actuator on the phone, such as one of the actuation positions of the 4-way navigation device (if part of the phone) or a soft key. Eatoni Ergonomics, the company that licenses the Letterwise algorithm for use in software for phones and other electronic devices incorporating multi-tap and other ambiguous keyboards, proclaims that the Letterwise algorithm has but two rules.

Rule 1: Tap the key of the 12-key phone keypad that is used to enter a desired text character. For example, to type ‘e’, press the 3 key, and to type ‘v’, tap the 8 key.

Actuation of a key provides input to the Letterwise algorithm which then guesses which letter or other text character that can be entered using that key is most likely intended given the preceding text, and then writes that guess to the display.

Rule 2: If the text character displayed is not the desired text character, keep tapping the Next key until the desired text character is displayed.

Once the desired text character is displayed, the user presses another key to enter the next text character. The order in which letters will be displayed corresponds, in diminishing order, to the probability a text character entered using that key will appear in that position in the text.

In sum, the Letterwise algorithm is: tap the key for entering the desired text character and if the desired text character is not the one displayed with the first tap, tap the Next key again and again until it is the one displayed. Then enter the next text character by tapping the appropriate key.

Enabling a keyboard to emulate a multi-tap keyboard operating under the Letterwise algorithm is therefore relatively simple. As an illustrative example, keyboard 150 will be enabled to emulate a 12-key multi-tap phone keypad running Letterwise software. First, define a Next key. Any of center button 165, key 156, or key 157 will do so we will define center button 165 as the Next key.

Then use the method described above to create rules of operation that will allow the emulating keyboard to definitively indicate which key of the multi-tap keyboard running Letterwise software is used to enter a particular data string. Finally, as noted above, keyboard 150 must be operating under Letterwise-like letter-by-letter PT software or the typable device 161 of which keyboard 150 is a part must be running Letterwise-like letter-by-letter PT software.

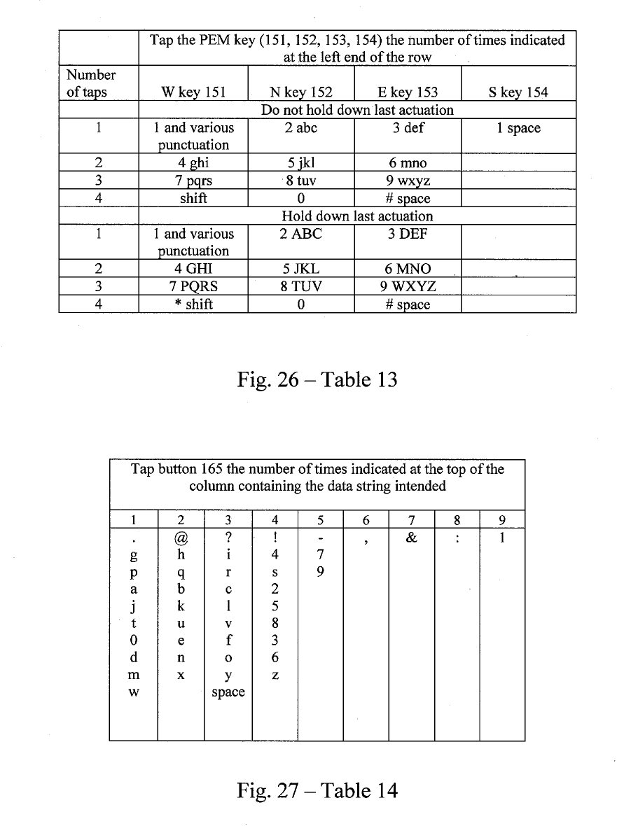

The PEM will be defined as keys 151, 152 and 153. The first parameter input mechanism will be PEM key choice-PIM and serves to enter second input parameter 21-2 (Column-IP as defined in FIG. 6). Actuating PEM key 1411 indicates that the key of the 12-key keypad 2100 used to type the desired data string is in the first column of keys, actuating PEM key 1412 indicates it is in the second column, and actuating PEM key 1413 indicates it is in the third column. The second parameter input mechanism is PEM number-PIM and serves to enter first input parameter 21-1, Row-IP. If the PEM key used is actuated once, the first and top row of the 12-key phone keypad is indicated as the row in which the key to enter a desired data string is located; if it is actuated twice, the second row is indicated; if it is actuated thrice, the third row is indicated; and if it is actuated four times, the fourth and bottom row is indicated. The third parameter input mechanism is last last hold-PIM and serves to enter the fourth input parameter 21-4, shift-IP; holding the last actuation down for longer that X seconds indicates use of the shift key. Table 12 in FIG. 25 shows these PIM-IP assignments and definitions, and Table 13 in FIG. 26 shows the keyboard setup that results from them. Note that operation of keyboard 150 under the keyboard setup shown in Table 13 in FIG. 26 does not uniquely identify a data string, but rather it identifies a subset of the data strings the 12-key phone keyboard is capable of entering; thus the need for keyboard 150 to also be operating under a predictive text algorithm.

Operation of keyboard 150 under the keyboard setup in Table 13 in FIG. 26 and the Letterwise is as follows:

Tap the PEM key 151, 152, or 153 that indicates the column in which the key for entering a desired data string is found on the 12-key phone keypad a number of times that indicates the row in which such key is found. The operating software for the keyboard 100 will interpret this actuation sequence in the same way the Letterwise-like letter-by-letter PT algorithm software operating the phone keypad would interpret a press of the indicated key, and it will make a guess as to which text character is intended, and display that guess.

If the text character displayed is not the desired text character, keep tapping the Next key, button 165, until the desired text character is displayed.

Once the desired text character is displayed, go back to step 1 to enter the next data string. If the key indicated in step 1 is not a text character key, and thus not one that requires Letterwise, enter the data string that that key on a 12-key phone keypad would enter. Since S key 154 is not required for emulating the 12-key phone keypad, it can be used for other purposes, such as to enter spaces. Keys 156 and 157 can be used for purposes such as backspace and delete. Series of multiple actuations of both S key 154 and key 157 can also be used to enter data strings, and either or both can be defined as a TEM, thereby increasing the number of usable actuation sequences. Letterwise allows definitive text entry as a matter of course (you don't move on to the next letter until Letterwise gets the current one right) and in numeric mode there is only one data string per key so no separate definitive text entry mode is needed. Since only four keys were used to emulate the 12-key phone keypad running Letterwise-like letter-by-letter PT software (five if you count the actuator used for entering spaces), any keyboard comprising at least four (or five if a separate space key is desired) can operate under the keyboard setup in Table 13. Examples are keyboards 100, 1400, 500, 130, 1800, and 800.

In an alternate embodiment of the operating rules for keyboard 150, the button 165 is defined to have a different function than operating as the Next key for a letter-by-letter PT program. In this embodiment, the button 165 operates as the SEM number-PIM for entering the tap order-IP, just as it would under the Version 2 keyboard setup. Under this embodiment, the actuation sequence under the keyboard setup in Table 13 in FIG. 26 is executed to indicate the key of the emulated keyboard used to enter a particular text character and whether the text character is capitalized is completed. If the letter-by-letter PT algorithm's guess is correct, the user can start executing the actuation sequence for the next data string to be entered. However, if the letter-by-letter PT software makes an incorrect guess as to which text character the user intended to enter, the user then executes the second step of the actuation sequence under the Version 2 keyboard setup for that text character (Table 14 in FIG. 27 shows that portion of the actuation sequence only and contains instructions on how to apply it to data strings). In effect, under this embodiment, the operating software for text entry takes advantage of the fact that the column and row of the key used to enter the text character and whether the text character is capitalized has already been input by execution of the actuation sequence under the keyboard setup of Table 13, and only the position of the text character in the tap order of the indicated key remains to be input for the keyboard or typable device's operating software to be able to definitively identify the data string the user intends to enter. Upon completing both actuation sequences, the net effect is to have executed the actuation sequence for that text character under the keyboard setup shown in Table 6 in FIG. 10, otherwise known as Version 2.

In summary, the rules of operation under this embodiment of keyboard 150 emulating a 12-key phone keypad operating in PT mode are as follows.

Execute the actuation sequence for entering a desired text character under the keyboard setup in Table 13 in FIG. 26 (this involves actuating the one of the three PEM keys 151, 152 or 153 indicating the column in which the key to enter that text character is located a number of times indicating that key's row, and holding or not holding the last actuation to indicate the text character's capitalization). For example, to enter an ‘n’ tap the E key 153 twice; to enter ‘U’ tap the N key 152 thrice, holding down the last actuation; and to enter ‘7 ’ actuate W key 151 three times.

If the text character guessed by the PT algorithm is correct, go to step 1;

If the text character guessed by the PT algorithm is incorrect, execute the actuation sequence for entering that text character under the keyboard setup in Table 14 in FIG. 27 (this involves actuating the button 165 a number of times equal to that text character's place in the tap order of the key that enters it). For example, the actuation sequence for entering ‘k’ is to tap button 165 twice; for entering ‘&’ is to tap button 165 seven times; and to enter a space is to tap button 165 three times. Then go to step 1.

The electronic device 161 comprising the keyboard 150 and the display 162 can be a phone, PDA, handheld computer, GPS device, MP3 player, video player, digital camera, electronic game, entertainment device remote, radio, TV, DVD player, or any other type of electronic device incorporating a keyboard or any typable device. The keyboard 150 incorporated into the electronic device 161 can enter text by emulating a phone keyboard incorporating a 12-key phone keypad or TenGo keyboard incorporating a 6-key keypad (or any other compact or non-compact keyboard with an appropriate structure) operating in multitap text-entry mode or operating under any predictive text algorithm, including Letterwise, T9, TenGo, iTap or another predictive text algorithm.

### Emulating Keyboards Using Word-by-Word Predictive Text Algorithms

T9 is a word-by-word predictive text algorithm which, like Letterwise, is implemented in software for the purpose of reducing the number of keystrokes required to enter text using a phone keyboard. It typically employs the 12-key phone keypad, the four actuators of the 4-way controller, and two soft keys (different manufactures use different combinations of actuators). The 12-key keypad is typically used to type the text characters. Under the T9 algorithm, the user only taps each key of the 12-key phone keypad once. Since each key typically can enter multiple text characters, the specific text character the user intends to enter by pressing that key is ambiguous. As the user enters a string of text characters, the T9 algorithm tries to predict or guess what word or text character string (‘@%9’ and ‘road’ are examples of text character strings or text strings) the specific sequence of key actuations made since the last space is meant to enter. Since more than one text character can be entered using most keys of a 12-key phone keypad in text mode, there is usually more than one word choice. For example, typing 2-2-5-3 can spell ‘able’, ‘cake’, ‘bald’ and ‘calf’, among others words. T9 tries to guess which one the user intended to enter by looking in its dictionary for words that are typed using that specific sequence of keys, and by referring to a table of probabilities to see which of the possible words found in the dictionary is most probable. With T9, the predicted words will contain only as many text characters as the user has entered.

The rules for T9 on a 12-key phone keypad are more complicated than those for Letterwise, and are summarized below.

To Type:
a. Tap the key of the 12-key keypad that is used to enter the desired text character (for example, to enter w, x, y or z, tap the 9 key, and tap the 2 key to enter a, b or c). T9 tries to guess the word after each tap of a key, and displays each of its guesses, using the text characters already entered.
b. Continue tapping keys until you have finished typing all the text characters in the word you want to enter.
c. If the word displayed (i.e., T9's guess at the word) is not the word intended, tap the actuator defined as the Next (or Next Word) key (it is the down actuation position [S] of the 4-way controller on some phones using T9, but could be any actuator on the phone not used for text entry) until the correct word is displayed. There is also typically a Previous key as well (also defined as some key not used for text entry), in case the user goes past the intended word; some phone implementations of T9 use the Up actuation position of the 4-way controller [N] for this purpose.
d. Once the intended word is displayed, choose the word by tapping the Space key (often a key in the bottom row of keys of the 12-key keypad).

Non-Letter Keys:
a. To type punctuation, tap the 1 key and the T9 algorithm will guess which punctuation mark is intended
b. To capitalize a letter or letters, press the Shift key (often a key in the bottom row of keys of the 12-key keypad) before typing the letter or letters to be capitalized, and then press it again after typing that letter or those letters to return to lowercase
c. To type a number, press and hold down the key for that number (for example, to type 3, press and hold the 3 key down until the number 3 is displayed.

To add a new word to the dictionary (a ‘word’ can be any text string [i.e., string of text characters such as letters, numbers, symbols and punctuation]), press the Spell actuator (one of soft keys of the phone keyboard is often used for this purpose by the T9 software). This turns off T9 text entry mode and activates multitap text entry mode. The user first enters the new word using multitap, then presses Save (the same or a different soft key) to enter the just-typed word into the dictionary. Multitap entry mode is the standard for entering text characters using a phone keypad; letters are entered by pressing the key to which they are assigned (the labels of which they usually appear in) a number of times corresponding to their place in the alphabetic order of keys assigned to the key (in multitap text mode, the numbers typically follow the letters assigned to the key in the tap order [i.e., the order based on the number of presses required to enter the character], and sometimes the user can also enter capital letters or punctuation with the letter keys by pressing a key enough times).

Other Functions:
a. Clear—press the actuator used for this purpose to delete the last keystroke (the back position [W] of the 4-way controller is used for this purpose in some T9 setups).
b. Compound words—this is too complicated to explain here, but the right pointer position [E] of the 4-way controller is often used for in this function in implementations of T9 using a phone text-entry interface.

For the keyboard 150 to emulate a multitap phone keypad that is running T9-like word-by-word PT software, it must be properly setup. Phone keypads running T9-like word-by-word PT software typically use more than just the 12-key phone keypad. They often use the soft keys (cell phones typically have at least two, one under each corner of the display, and often the key in the middle of the 4-way controller is a soft key at times), and the actuation positions of the 4-way controller, and may use other of the actuators typical on a phone keypad such as the OK button in the middle of the 4-way controller, the Clear button, and the Send and End buttons. These extra keys are not typically used for text input, but for triggering functions (such as scrolling through a list of word guesses or adding a word to the dictionary) or for changing mode. Therefore, in order to emulate a phone text-entry running under a T9-like word-by-word PT algorithm, the keyboard 150 will have to emulate more than just text entry, but will also have to emulate the functions of the other actuators used by T9-like word-by-word PT algorithms on a phone keyboard. Although some implementations of T9-like word-by-word PT algorithms may have fewer extra functions and therefore may utilize fewer actuators in addition to those of the 12-key keypad, in the description below, the keyboard 150 emulates a phone keyboard operating under T9-like word-by-word PT algorithm software comprising a 12-key phone keypad, a 4-way controller with a center button (which may be a soft key whose function changes, its current function indicated by a label appearing above it on the display), and two soft keys.

First, however, the text-entry keyboard setup for keyboard 150 must be chosen. Since T9-like word-by-word PT algorithm-enabled phones use the 12-key phone keypad to enter text characters, Version 2 described above will be used in this embodiment because under Version 2 actuation of a single actuator of the keyboard 150 (albeit sometimes multiple times) identifies the phone keypad key used to enter a desired letter. When entering new words not in the T9-like word-by-word PT dictionary, users of T9-like word-by-word PT algorithm-enabled keyboards switch to multi-tap mode to definitively identify the text characters in the word or string, and the Version 2 method of emulating the phone keypad can also emulate multi-tap text entry mode on a phone keypad and definitively enter specific text characters. The PIM-IP assignments and definitions used above in the Letterwise example and shown in Table 12 in FIG. 25 and which result in the keyboard setup in Table 13 cannot be used without modification because pressing and holding down the last actuation is used to enter numbers. Therefore, the final PIM will be changed to holding down the last actuation for at least Y seconds (e.g., 1 second); if the last actuation is held down for at least X seconds (e.g., 0.5 seconds) but less than Y seconds, the number associated with the indicated key will be entered, and if it is held down for at least Y seconds, capitalization will be indicated. The labels for the PIM in Table 12 in FIG. 25 and the last actuation related labels in Table 13 in FIG. 26 should be appended with the phrase “for at least 1 second.” The keyboard setup in Table 13 can now be used for keyboard 150 while operating in PT mode while Version 2 will be used as is while keyboard 150 is operating in definitive text mode. The two are compatible with the only difference being that no SEM actuation is required while operating in PT mode.

Second, the three actuators to emulate the 12-key phone keypad and operate as the PEM must be chosen. The PEM keys will be W key 151, N key 152 and E key 153 which will operate like keys 1411, 1412 and 1413 of keyboard 1400 in the keyboard setup in Table 6 in FIG. 10. When keyboard 150 is operating in definitive text entry mode to emulate the 12-key phone keypad operating in multi-tap mode, button 165 will operate like key 1401.

More than just the twelve keys of the phone keypad are used by T9-like word-by-word PT software in most implementations. Additional actuators are used for several additional functions, including Previous Word, Next Word, and Clear, and, in some versions of T9, Compound Word Typing (which will be referred to here as the Special Function Key). Soft keys are also used for Spell and Save. In some implementations of a T9-like word-by-word PT algorithm on some phones, the four actuation positions of a 4-way controller are used for these functions, such as using S 104 for Next Word, N 102 for Previous Word, W 101 for Clear and E 103 as the Special Function Key. In one embodiment of keyboard 150, the actuation positions of the 4-way controller 160 and the center button 165 are used for both text entry and for executing these functions. For this embodiment, the center button 165 functions as the Next Word key and, once the center button 165 has been pressed, and until a space is entered or enough time passes (more than some prespecified duration), the N key 152 functions as the Previous Word key, the W key 151 functions as the Clear key, and the E key 103 functions as the Special Function Key. Since the S key 154 is not used in this embodiment for either entering text characters or for one of the above-mentioned additional functions, the S key 154 is used in the same way that the space key is used in T9-like word-by-word PT algorithm-enabled keyboards (e.g., to accept a word and enter a trailing space).

In addition, T9-like word-by-word PT algorithm software often employs soft keys, which can have several different functions as necessary, with the current function of the soft key indicated by a label on the display above the soft key. For example, to add a new word into the T9 dictionary, the user presses the soft key labeled ‘Spell’ and then types in the new word, and after the word is typed, presses the soft key labeled ‘Save’ to save it in the dictionary. Left key 156 and right key 157 are soft keys and can serve this purpose. In embodiments of keyboard 150 without keys 156 and 157 (or when using keyboard 130), actuators of the 4-way controller 160 (or the click wheel 120 of keyboard 130) can serve this purpose. For example, pressing and holding the center button 165 for at least some pre-specified time can trigger the ‘Spell’ function for entering a new word into the dictionary, and can be used to trigger the ‘Save’ function after the word is spelled definitively.

Now that the keyboard 150 had been ‘set up’ for emulating a phone keypad operating under a T9-like word-by-word PT algorithm, it is time to describe the emulation will be accomplished. Following are the T9-like word-by-word PT algorithm operations that a user would perform in bold, with the way that operation is done using the keyboard 150 and the way the operation is done using a 12-key keyboard running a T9-like PT program in separate bullets below. Note that the emulation by the keyboard 150 will require a T9-like word-by-word PT algorithm for guessing what text characters the series of keys indicated were intended to enter.

Type/Enter Text Character (e.g., Letter, Number, Punctuation):
a. Keyboard 150: Tap the appropriate key 151, 152 or 153 the appropriate number of times to indicate the key of the 12-key phone keypad that is used to enter a desired text character—for example, to indicate the 2 key, tap N 152 once.
b. 12-key keypad: Tap the key that is used to enter the desired text character

Type/Enter Word:
a. Keyboard 150: Continue entering text characters by indicating the key of the 12-key phone keypad used to enter each until the word is complete
b. 12-key keypad: Continue to enter text characters by tapping the key used to enter each until the word is complete

If the first string of text characters displayed is not the string intended, scroll through word choices until the correct string of text characters is displayed:
a. Keyboard 150: Tap the actuator designated as the Next Word key (the center button 165 in this embodiment) until the correct string of text characters is shown on display 162; once the Next Word key 165 has been actuated at least once, and until a space is entered or a predetermined amount of time has passed since the last actuation, the N key 152 operates as the Previous Word key, the W key 151 functions as the Clear function, and the E key 153 functions as the Special Function key. Once a space has been entered or enough time has passed since the last actuation, the W 151, N 152 and E 153 actuation positions will again operate to enter text characters.
b. 12-key keypad: If the word displayed is not the word intended, tap Next Word key until the correct word is displayed. Typically, the Previous Word and Clear functions are always available.

Accept Displayed or Selected Word:
a. Keyboard 150: Accept the word displayed by pressing the key designated as the Space key, the S key 154; this accepts the word and types a trailing space
b. 12-key keypad: Accept the word by tapping the Space key; this accepts the word and types a trailing space

Type Punctuation:
a. Keyboard 150: Indicate the 1 key by tapping the W key 151 once
b. 12-key keypad: Tap the 1 key once

Type Number:
a. Keyboard 150: Hold down the last actuation in the actuation sequence executed to indicate the desired number key of the phone keypad. For example, to enter 8, tap the N key 152 twice, holding the key down on the last actuation for at least X seconds but less than than Y seconds (for example, X=0.5 seconds, Y=1.0 seconds)
b. 12-key keypad: Press and hold the key for that number

Capitalize:
a. Keyboard 150: Indicate the shift key [the * key in the phone keypad being emulated here] by tapping the W 151 four times, or hold down last actuation for longer than for 1 second before entering the letter or letters to be capitalized, and then do the same after the last of the letter or letters to be capitalized has been entered
b. 12-key keypad: Press the Shift key (the * key of the particular phone interface being emulated) before the letter or letters to be capitalized are entered, and then do the same after they have been entered

Add New Word to Dictionary:
a. Keyboard 150: Use soft keys 156 and 157 as they are used for T9 on a standard phone interface. (For a keyboard having no soft keys, define a special actuation of a particular actuator [such as holding down the button 165 at least some specific amount of time] to trigger Spell mode which will switch keyboard 150 into multitap mode for definitive entry (the keyboard setup Version 2), and then do the same to trigger the Save function to save the word in the dictionary and return to emulating T9 text entry mode. The soft keys can function identically to how they would function under T9 operating on a phone keypad.
b. 12-key keypad: Press the soft key functioning as ‘Spell’ which deactivates T9 text entry mode and returns to multitap text entry mode, then enter the word or string using multitap text entry. After finishing the entry of the word, press the soft key functioning as Save to enter the completed word into the T9 dictionary and return to T9 text entry mode.

Next Word:
a. Keyboard 150: press the center button 165 to scroll forward through the T9-type PT algorithm's word guesses
b. 12-key keypad: Press the actuator designated as the Next Word actuator to scroll forward through the T9 PT algorithm's word guesses.

Previous Word:
a. Keyboard 150: press the center button 165 and then press the N key 152 (defined as the Previous Word key in this embodiment); this scrolls backwards through the T9-type PT algorithm's word guesses.
b. 12-key keypad: Press the actuator designated as the Previous Word actuator, often the up/N actuation position of a 4-way controller, to scroll backwards through the T9 PT algorithm's guesses.

Clear Letter:
a. Keyboard 150: press the center button 165 and then press the W key 151 (designated as the Clear key in this embodiment); entering a space deactivates the Clear function operation of the W key 151 and returns it to entering text characters.
b. 12-key keypad: Press the actuator designated as the Clear actuator, often the left/W actuation position of a 4-way controller

Special Function Key for Entering Compound Words:
a. Keyboard 150: press the center button 165, and then press the E key 153 [the actuator designated as the Special Function Key actuator in this embodiment] as you would use the equivalent key under T9 on a 12-key multi-tap keyboard; entering a space deactivates the Special Function Key function operation of the E key 153 and returns it to entering text characters.
b. 12-key keypad: Press the actuator designated as the Special Function Key actuator, often the right/E actuation position of a 4-way controller

FIG. 12 shows electronic device 133 incorporating the keyboard 130 comprising a touch sensitive click wheel 120 with four actuation defined positions W 121, N 122, E 123 and S 124, a button 125 in the center of the click wheel 120 and a display 132. Keyboard 130 operate under the keyboard setups and rules of operation described above for the keyboard 150 when emulating a 12-key multi-tap phone keypad operating under a letter-by-letter PT algorithm like Letterwise and under a word-by-word PT algorithm like T9, with actuation positions W 121, N 122, E 123 and S 124 and button 125 of keyboard 130 operating the same as keys W 151, N 152, E 153 and S 154 and button 165 of keyboard 150 respectively, and a clockwise stroke of the click wheel 120 at N 122 operating like left soft key 156 and a counterclockwise stroke at N 122 operating like right soft key 157.

The touch sensitivity of click wheel 120 opens up other actuation options. For example, running a finger clockwise around the click wheel 120 can scroll forward and running it counterclockwise can scroll backwards through word guesses of the PT algorithm. Alternately, moving a finger on the click wheel 120 clockwise from around 10:30 to 1:30 can operate as the Next Word key, and moving a finger counterclockwise from around 1:30 to 10:30 on the click wheel 120 can operate as the Previous Word key. Moving a finger clockwise from 4:30 to 7:30 can implement the Clear or backward delete function, deleting one text character for each stroke of the finger. To delete an entire word, the user can move a finger along the click wheel 120 from 3:00 to 9:00; one word is deleted for each such stroke. To delete an entire paragraph, the user can move a finger clockwise along the click wheel 120 from 12:00 back to 12:00. The Special Function operation can be done by moving the finger from 7:30 to 4:30 along the click wheel 120. Spell can be implemented by moving a finger along the click wheel 120 counterclockwise from 10:30 to 7:30. Moving a finger up (counterclockwise) from around 4:30 to 1:30 on the click wheel 120 can shift lock; all letters entered after this will be uppercase until the user moves his finger down (clockwise) from around 1:30 to 4:30 on the click wheel 120 to release shift lock. It will be obvious that many different finger movements on the touch-sensitive click wheel 120 can perform these and other functions. If the keyboard 130 comprises the click wheel of an Apple iPod, there are no soft keys 106 and 107, so the touch sensitivity of the click wheel can be used as just described to perform any function described above as being performed by the soft keys. The touch sensitive click wheel 120 can interpret not just presses of the click wheel to engage an actuator or switch and where on the click wheel a user presses, it can also track and interpret movements of a finger across its touch-sensitive surface. It is therefore possible to create a two new parameter input mechanisms, stroke-PIM and stroke/actuation-PIM. Stroke-PIM is the path of a user's finger in contact with the touch sensitive click wheel 120 from its point of initial contact until such contact is broken. This was previously described as being used for text entry functions such as clear and delete. Stroke/actuation-PIM is a set of defined finger strokes on the touch sensitive surface done in conjunction with an actuation of an actuation position 121-4. Each defined stroke/actuation pattern is interpreted by the emulating keyboard's operating software as a value for an input parameter. For example, if we want to enter four values for an input parameter (such as row-IP for emulating a phone keypad), we need to define four different stroke/actuation patterns. One simple set is stroke up, no stroke, stroke down and stroke up then quickly down. Another is stroke counterclockwise, stroke clockwise, stroke first counterclockwise then back clockwise, and stroke first clockwise and then back counterclockwise. Diagonal strokes, circular strokes, strokes that change direction (e.g., first left then right), and other stroke patterns can be used.

Strokes can take several forms. The timing of stroke and actuation can vary including: pressing then stroking while holding down the click wheel; stroking then pressing down and releasing the click wheel; pressing and releasing the click wheel then stroking; and pressing then stroking while releasing the click wheel. The stroke/actuation-PIM and another PIM (such as number-PIM) of the same actuator can be done together. The keyboard operating system can be set up to require a stroke be done on every actuation of the actuation position used or only the first (first-stroke/actuation) or last (last-stroke/actuation) actuation can require an accompanying stroke. In one embodiment using the above approach to emulate a 12-key phone keypad using a touch-sensitive click wheel keyboard, first-stroke/actuation-PIM can enter row-IP (for example, using the first simple set of four patterns above), number-PIM can enter column-IP using three of the actuators of the click wheel 120, and number-PIM using the center button 125 can be used to enter the tap order-IP. In this example, a ‘v’ would be entered by pressing the N actuator 122 (indicates middle column of phone keypad) while stroking down (indicates 3^{rd} row of phone keypad) and then pressing N 122 two more times (a total of three presses indicates 3^{rd} place in the tap order). This embodiment reduces the number of keystrokes or actuations required to type any data string definitively using keyboard 130 to the same number of keystrokes required to type the data string using the emulated phone keypad in multi-tap mode. This is quite remarkable for what is essentially a three key keyboard.

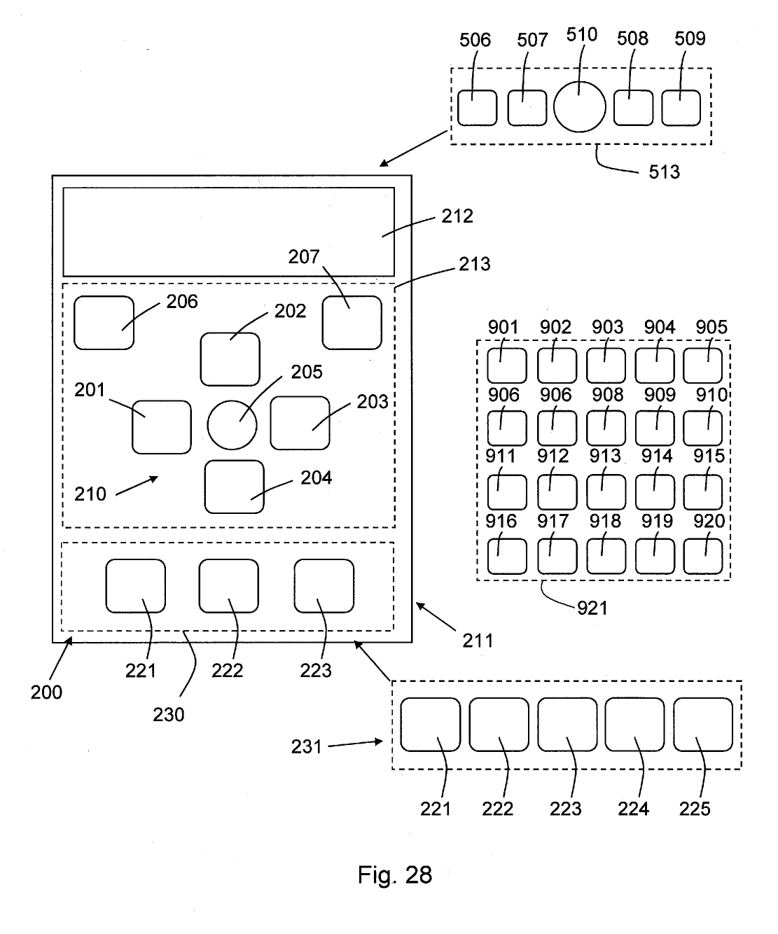

Keyboard 200 shown in FIG. 28 comprises a control interface 213 comprising a 4-way controller 210, comprising four keys, W 201, N 202, E 203 and S 204, equally spaced around an OK button 205 and at the four points of the compass (W, N, E and S), and, optionally, the left soft key 206 and the right soft key 207, and a 3-key keypad 230 comprising three keys aligned horizontally below the 4-way controller 210 (left key 221, middle key 222 and right key 223). Using the keyboard 200 to emulate a phone text-entry interface incorporating a 12-key phone keypad and running Letterwise-like letter-by-letter PT software is very similar to how such phone keyboard is emulated using the keyboard 150. The only difference is that the three keys 221, 222 and 223 of the keyboard 200 are used instead of keys W 151, N 152 and E 153 to execute the actuation sequences for entering text characters, and the four keys of the 4-way controller 210 and button 205 operate as they do in typical implementations of PT software on phones comprising a control interface similar to interface 213 and 12 multi-tap keys.

In one embodiment of keyboard 200 emulating a 12-key multi-tap keyboard operating under a T9-like word-by-word PT algorithm, the OK button 205 operates as the Next Word key, spaces are entered using the S key 204, the Clear function is accomplished by pressing the W key 201, N key 202 operates as the Previous Word key, E key 203 operates as the Special Function or Compound Word key, and capitalization is accomplished holding down the last actuation in the actuation sequence to enter a letter (just as with the implementation of T9 and other PT software on different phones, the assignments of function to key can be various). As with any of the disclosed keyboards, in other embodiments, the four actuation positions of the 4-way controller 210 and the OK button 205 can each be used for different functions, and the soft keys 206 and 207 can also be used for functions like clear, Next letter, shift, etc. The description above of how keyboard 150 can emulate a 12-key phone keypad operating under Letterwise-like and T9-like PT software applies to keyboard 200, with the appropriate actuator substitutions.

The keyboard 3500 in FIG. 11A can also be set up to emulate a 12-key phone keypad operating under a predictive text algorithm. Keyboard 3500 is very similar to keyboard 200 in FIG. 28 except that the subset of keys used to enter text on keyboard 3500 consists of four keys vertically aligned instead of three keys horizontally aligned, and keyboard 200 has two soft keys (keyboard 3500 could easily be modified by adding two soft keys). Both keyboards comprise a 4-way navigation device with a center button. The major difference between the operation of keyboard 3500 and keyboard 200, and for that matter keyboard 3500 and keyboard 150, is that a different keyboard setup is used under which instead of the PEM key actuated indicating the column of keys in which the key of the emulated keyboard used to enter a data string is located, the PEM key actuated indicates the row of keys in which that key is located, and instead of the number of times it is actuated indicating its row number, it indicates that key's column number. The net effect is to exactly specify the key of the emulated keyboard used to enter a particular data string. Also, under the keyboard setup of Table 6A in FIG. 11C, the first hold-PIM is used instead of the last hold-PIM to enter the shift-IP, which simplifies data string entry somewhat. If one substitutes a keypad comprising the four keys 3511-3514 for the keypad 230 comprising three keys 221, 222 and 223, the center button 3515 for button 205, the four navigation actuation positions 3501, 3502, 3503 and 3504 for keys 201, 202, 203 and 204 respectively, and either adds two soft keys to keyboard 3500 or assigns the soft key functionality to another actuator, the descriptions of keyboard 200 emulating a 12-key keyboard operating under a PT algorithm will apply to keyboard 3500.

Another word-by-word predictive text algorithm for 12-key phone keypads is iTap from Motorola. iTap works the similarly to T9, but whereas T9 predicts what the letters the user meant to type, iTap predicts whole words that start with the letters already typed, so the guessed word displayed may contain more text characters than have been typed by the user. Emulation of iTap using the keyboard 150 will thus be very similar to that of T9 described below, and adaptation of the description below to fit iTap will be simple for those of average skill.

Note that in the descriptions of the keyboards disclosed here, the primary focus is on how the keyboards are used to enter letters, punctuation and numbers, and not on other functions of the keyboards, such as deleting mistakes and capitalization. Some implementations of PT algorithms have limited functionality while others have extensive functionality, and the implementations of PT algorithms on the disclosed keyboards described here may have more or less functionality than a particular phone implementation, but the information disclosed herein is sufficient to enable one of average skill to adapt the disclosed keyboard to fully emulate that phone implementation. The use of the keyboard 150 and 130, with or without the soft keys, to emulate phone keyboards incorporating 12-key phone keypads is not limited to those using Letterwise, T9 and iTap text entry modes, but can, with adjustments that will be obvious to the skilled practitioners, emulate phone keyboards with any key layout and using any text entry mode for improved efficiency.

Research-in-Motion's (RIM) Blackberry SureType keyboards operate under RIM's SureType predictive text software or in multi-tap mode. Each key of the SureType keyboard can be used to enter one or more text characters. Operating under SureType PT software, the SureType keyboard with its 20-key keypad works similarly to phone keyboards incorporating a 12-key keypad operating under T9 software. Individual text characters are entered by pressing the key used to enter the desired text characters once, and text is entered by entering a string of text characters. The SureType algorithm guesses the text characters the user intended to enter on a word-by-word basis, like T9 guessing only as many text characters as the user has typed since completing the last word by entering a space.

In one embodiment of the typable device 211 shown in FIG. 14, keypad 230 of keyboard 200 is replaced by keypad 231 having two extra keys 224 and 225 horizontally in line with the original three keys 221, 222 and 223. We will refer to this embodiment as keyboard 230A. When keyboard 230A is operating in definitive text entry mode, the five keys 221-225 will be defined as the PEM and OK button 205 will be defined as the SEM. The first parameter input means will be PEM key choice-PIM which will serve to enter the column-IP, with key 221 indicating that the key of the 20-key SureType keyboard used to enter a particular data string is in the first column, key 222 indicating that the key is in the second column, key 223 indicating it is in the third column, key 224 indicating it is in the fourth column and key 225 indicating it is in the fifth column. The second parameter input means will be PEM number-PIM which will serve to enter the row-IP, with one tap indicating that the key of the 20-key SureType keyboard used to enter a particular data string is in the first row, two taps indicating it is in the second row, three taps indicating it is in the third row and four taps indicating it is in the fourth row. Executing the PEM step of the actuation sequence specifies exactly the key of the SureType 20-key keyboard that is used to enter a data string. The third parameter input means will be SEM number-PIM which will serve to enter the tap order-IP with the number of taps equal to the data string's position in the indicated key's tap order. Capitalization can be indicated by a fourth PIM, last hold-PIM to enter the shift-IP, with holding down the last actuation indicating that the shift key is used to type the data string using the 20-key SureType keyboard.

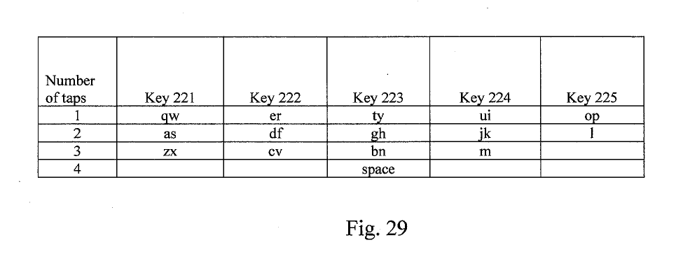

Keyboard 200A can emulate a 20-key SureType keyboard running word-by-word PT software such as T9 or SureType. Since the SureType PT software operates very similarly to T9 software, we will reference the description of keyboard 200 comprising 3-key keypad 230 emulating a 12-key phone keypad operating under T9-like PT software. Keyboard 200A comprising 5-key keypad 231 operates exactly the same as keyboard 200 except that the operation of “type/enter text character” will change to: tap the appropriate key 221, 222, 223, 224 and 225 the appropriate number of times to indicate the key of the SureType 20-key keyboard that is used to enter a desired text character. The keyboard setup for keyboard 200A when emulating a SureType keyboard running T9-like PT software is shown in Table 15 in FIG. 29.

Keyboard 200A can also emulate a 20-key SureType keyboard running letter-by-letter PT software like Letterwise. The first step in entering a data string using keyboard 200A is to tap the appropriate key 221, 222, 223, 224 or 225 the appropriate number of times to indicate the column and row of the key of the 20-key keyboard used to enter a particular data string, holding the last actuation if the data string is a letter to be capitalized. The letter-by-letter PT algorithm will guess which letter was intended. If the guess is correct, start entering the next data string. If the guess is incorrect, press the OK button 205 once to select the other data string the indicated key can enter (the keys of the SureType 20-key keyboard have only two data strings assigned to each key). Then start entering the next data string. For improved efficiency, the S 204 key can be used to enter spaces.

Some electronic devices incorporating a SureType 20-key keyboard have a different control interface from control interface 213. For example, the Blackberry Pearl comprises a control interface 513 comprising a trackball 510 with two keys on either side and aligned horizontally with it 510, a send key 506 and a menu key 507 on the left, and an escape key 508 and an end/power key 509 on the right. In another embodiment of keyboard 200A comprising 5-key keypad 231, keyboard 200B comprises control interface 513 and the five-key keypad 231. Keyboard 200B can emulate a 20-key SureType keyboard operating under a T9-type PT algorithm (define the appropriate function keys in control interface 513) or under a Letterwise-type PT algorithm (use the trackball 510 or another key in the control interface 513 to select the other data string entered by the indicated key if the guess is wrong).

The keyboard 150 can be used to emulate a TenGo keyboard operating under the TenGo predictive text algorithm. For entry of letters, a TenGo keyboard comprises a keypad comprising six keys in three rows of two keys (or two columns of three keys each), and a space key below. In many implementations of the TenGo keyboard in typable devices the keys are virtual keys on a touch sensitive display. In order, top to bottom, left to right, the six letter keys of the TenGo keyboard enter the following text characters: top left key—q, w, e, r, t; top right key—y, u, i, o, p; middle left key—a, s, d, f, g; middle row right—h, j, k, l; bottom row left key—z, x, c, v, b; bottom row right key—n, m. The space key enters spaces.

To emulate the TenGo keypad using keyboard 150, the row-IP and column-IP will be used to specify the location of the key used to enter a desired text character on the TenGo keyboard, the tap order-IP will be used to indicate the position of the desired text character in the tap order of the key identified by the row-IP and column-IP, and the shift-IP will be used to indicate whether the letter is capitalized. Because it makes it easier to implement predictive text algorithms, we will select parameter input mechanisms that will enable input of both the row-IP and column-IP with a single key, and will make that key and these two PIMs the PEM. There are two columns, so the PIM to enter column-IP must have two options; we will use the key-PIM to enter the column-IP and will use W key 151 and E key 153, with the W key 151 indicating the left-hand column and the E 153 indicating the right-hand column. There are three rows of letter entry keys, so a PIM with at least three options will be needed to enter the row-IP. We will use the number-PIM, with the number of actuations of keys 151 or 153 indicating the row, counting top to bottom. The maximum number of letters assigned to each key is five, so a PIM having at least five options is needed. We will use the number-PIM to enter the tap order-IP, and will select the button 165 as the actuator used to enter it, with the number of taps of button 165 being the same as the number of taps of the TenGo keyboard key used to enter a particular text character. The last hold-PIM will be used to enter the shift-IP, with holding the last actuation indicating use of the shift key and, for letters, capitalization. We will assign the keys 151 and 153 to the PEM, and the button 165 to the SEM. Thus to use keyboard 150 to enter a ‘d’, the user taps the left key 151 twice and the button 165 twice, and to enter ‘P’ the user taps the right key 153 once and the button 165 five times, holding the last actuation down for at least some predetermined length of time. The actuation sequence for the keyboard setup associated with these PIM-IP definitions and assignments is first the PEM actuation entering row-IP and column-IP, then the SEM actuation entering the tap order-IP and the hold-IP.

Now that emulation of multi-tap mode of the TenGo keyboard is enabled on keyboard 150, emulation of a TenGo keyboard operating under the TenGo word-by-word PT algorithm will be enabled. Since in PT mode, the user only presses each key once, the emulating keyboard 150 need only indicate the key that is used to enter a particular text character. Since the PEM actuation does this, only the PEM actuation need be executed. Since we still want to indicate capitalization, the PEM for PT mode of the emulating keyboard will be changed by adding the last hold-PIM to enter the shift-IP. To choose a word other than the one predicted by the TenGo-like predictive text algorithm that must be running on the emulating keyboard, or to select another letter (such as one with accents), a Next key is used to scroll through the list shown, with the N key 152 functioning in this embodiment as the Next key, and once the correct string of text characters (word) or letter is indicated, the user can press S key 154 to accept it and enter a trailing space. The TenGo algorithm when operating with a virtual keyboard allows the equivalent of multitap text character entry, which it calls ‘scribing.’ It also allows the entry of accented versions of the letters being typed. This function is performed with the keyboard 100 by using the Next key 152 after a letter has been multitap-entered (i.e., by definitive text entry mode) to scroll through a list of accented versions of the letter. To accept an accented version of the letter that has been scrolled to (normally, this would mean that it was highlighted in some way once the Next key 152 had been pressed enough times to do so), the user either presses space or starts to enter the next text character.

Other functions that may be necessary for text entry are number entry or numeric mode, clear or backward delete, and punctuation entry. These may be accomplished in many ways, including the ways already described. For example, the key 156 can function as the clear or backward delete key and punctuation can be entered by pressing and holding the S key 154. Alternately, pressing the Next key N key 152 can change the operation of the W 151 and E 153 actuators to be shift and clear until the Next key 152 is pressed again or a space is entered.

Numbers can be entered in several ways. However, first the user has to switch to numeric mode. This can be accomplished in a number of ways, such as by pressing and holding the button 165 for at least some amount of time. Another is to use soft keys 106 and 107. Once in numeric mode, one way to enter numbers with the keyboard 150 is to emulate a 12-key numeric keypad and indicate the number key on that keypad (for example, to enter ‘4 ’ press W key 151 twice, to enter ‘0 ’ press N key 152 four times, and to enter ‘9 ’ press the E key 153 three times. A second way to enter numbers while in numeric mode is to enter the numbers 1 to 5 by pressing the W key 151 a number of times equal to the number being entered and entering the numbers 6 to 9 and 0 by pressing the E key 153 a number of times equal to the absolute value of the number being entered minus 5.

Note, any keyboard having at least four actuators can emulate the TenGo keyboard operating under multi-tap or PT mode, including keyboard 100. If using keyboard 100 to emulate a TenGo keyboard, one preferred embodiment is to use the left key 101 as a substitute for the left key 151 and the right key 102 as a substitute for the right key 151.

The emulating keyboard operating under letter-by-letter predictive text software can also operate as follows. The letter-by-letter PT algorithm can guess the data string being entered after each change to a different actuator and after each pause of at least a prespecified duration, and display that guess on the display screen. If the wrong data string is guessed, the user simply continues executing the rest of the actuation sequence. If the PT algorithm guesses the right data string, the user can immediately start entering the next data string. If, in addition, the first hold-PIM is used instead of the last hold-PIM, the first part of the actuation sequences in PT mode (i.e., operating under PT software) and in definitive text entry mode will always be the same, and incorrect guesses will be corrected simply by completing the actuation sequence for the intended data string.

To illustrate how this works, several examples will be given using the keyboard setup expressed in Table 6A in FIG. 11C for keyboard 3500. The user wants to enter the word ‘QUIT’. First, the user presses the third key 3513 once to specify that text character that he wants to enter is entered using the key in the third row of the first column of the phone keypad, and holds the first and only actuation long enough to specify that the shift key is used. The operating software will know that the intended text character is one of the following text characters: p, q, r, s, or 7. However, ‘q’ is not commonly used, so it is likely that the letter-by-letter PT algorithm under which keyboard 3500 is running as it emulates a phone keypad operating under the same will guess ‘r’ or ‘s’, both of which are statistically much more likely to be used to start a word and both of which are incorrect. The user observes the incorrect guess, and then proceeds to actuate the button 3515 twice to finish the actuation sequence and definitively enter ‘Q’. The user then types the next letter in QUIT, pressing the third key 3513 twice to enter the letter ‘T’, holding down the first actuation. Because ‘u’ is the most common text character that appears after ‘q’, the emulating keyboard's 3500 PT algorithm will guess ‘U’ (it knows it is capitalize already). The user will observe the correct guess and begin entering the next letter in QUIT. The user will press the second key 3512 once, holding the first actuation, and if the PT algorithm's guess is correct will begin entering the ‘T’, otherwise he will press button 3515 three times. To enter ‘T’ he will press third key 3513 twice, holding the first actuation. If the guess is right, he is done, and if it is wrong, he will press the button 3515 once.

The same approach can be used if the emulating keyboard is emulating a keyboard operating under word-by-word PT software, although with slight changes. Word-by-word PT algorithms make a guess after each key is pressed. Some guess only the number of letters that have already been entered in a word while others try to guess the entire word. The following approach can be used by either method. To enter a word, the user operates the actuators of the emulating keyboard (such as using keyboard 3500 operating under the keyboard sequence in Table 6A to specify the key in the second row of the second column—press key 3512 twice) to specify the keys of the emulated multi-tap keyboard used to enter the text characters of the word he wants to enter. After each text character is typed (i.e., its key is specified), the user can check the guess being made by the PT algorithm. If the guess for the latest text character typed is wrong, the user can complete the actuation sequence for that text character, thereby specifying exactly that text character. Knowing any of the text characters exactly will improve the guesses by the PT algorithm. This approach can be used with any of the emulating keyboards herein operating under a PT algorithm.

A variation of this approach can be used for word-by-word PT algorithms only. After typing any of a word's text characters by specifying the key of the emulated keyboard used to enter it, a user can check the word or string of text characters guessed by the word-by-word PT algorithm. If the guess is wrong, and especially if it is way off, the user can make an on-the-fly correction to the first letter in the word that has not already been definitively or exactly specified by executing the previously unexecuted SEM portion of the actuation sequence for that letter and not for the letter just entered. In other words, after executing the PEM portion of the actuation sequence for one text character and noticing that the PT algorithm is guessing wrong, the user finishes executing the actuation sequence for an already entered text character by executing the SEM portion of its previously incomplete actuation sequence.

An example will make this clearer. Keyboard 3500 will again be used, operating again under the keyboard setup in Table 6A in FIG. 11C and emulating a phone keypad such as keypad 2100 operating under a word-by-word PT algorithm that only guesses as many letters as have been entered (or at least for which the key used to type them has been indicated). Let's say the user is trying to enter the word “calf”. The same keys that are used to enter ‘calf’ (2253) can also enter ‘cake’, ‘able’, ‘bake’ and ‘bald’. To enter ‘calf’ the user executes the actuation sequences necessary to specify the 2 key twice (press key 3511 twice), then the 5 key (press key 3512 twice), then the 3 key (press key 3511 thrice) of the phone keypad. Let's say that after specifying the 2 key twice and the 5 key the user notices that the guess is ‘bal’ and decides that this would be a good time to provide the PT algorithm with more information it can use to improve its guesses. In the PT algorithm described above, he would finish the actuation sequence of the current text character, the ‘l ’ by pressing button 3515 three times. In this new PT algorithm for emulating keyboards, the user instead finishes the actuation sequence of the first letter in the word, ‘c’, by pressing button 3515 three times. Now the PT algorithm knows that the word starts with ‘c’, and will make a new guess.

A second example with a different PT algorithm will help. Keyboard 3500 will again be used, operating again under the keyboard setup in Table 6A in FIG. 11C, but this time emulating a phone keypad such as keypad 2100 operating under a word-by-word PT algorithm that tries to predict the entire word being entered from the letters already typed (or at least for which the key used to type them has been indicated). Let's say the user is trying to enter ‘calfs’ and has already specified the 2 key twice and the 5 key once in the way described in the preceding paragraph, and has already definitively specified the first text character in the word being typed as a ‘c’. If the user specifies the 3 key by pressing PEM key 3511 thrice, and the guess comes up wrong again, the user can operate the SEM button 3515 to finish the actuation sequence of the first ambiguous text character in the word being typed, which in this case is the second text character in the word (the first has already been definitively and exactly specified). In this case the user would press the SEM button 3515 once to specify definitively that the second text character is an ‘a’. This approach has the advantage that the user can use it to enter a new word not in the PT algorithms dictionary simply finishing the actuation sequence for each text character in the word in order. After each pause the user checks the guess and if it still incorrect, specifies definitively the next ambiguous text character in the word until either the PT guesses the word correctly or the user finishes executing the actuation sequences for all text characters entered ambiguously by only specifying the key used to type them and definitively specifies each of those text characters.

In an alternate embodiment of this correction mechanism for word-by-word predictive text algorithms, the first time a user corrects a guessed word or string of characters, it is the first text character in the word whose actuation sequence is completed to definitively specify which of the text characters entered using the specified key is the correct one. However, the second and every subsequent time the user corrects a guess, it is the actuation sequence the first part of which was just executed that is completed, the actuation sequence for the text character just entered. For the first correction to a guess, this alternate embodiment will operate as described in the previous paragraph—the first letter will be specified as a ‘c’ pressing the key 3511 three times and completing its actuation sequence. If the user has just pressed the third 3511 key three times to indicate the 3 key (and that one of the text characters d, e, f and 3 is intended), and the PT algorithm's guess is still incorrect, the user can definitively specify last text character entered by finishing the actuation sequence for that text character, in this case for the ‘f’ by pressing the button 3515 three times. Any subsequent correction will also correct the just-entered text character.

These versions of PT algorithms take advantage of keyboard setups in which the PEM actuations exactly specify the key of the emulated keyboard used to enter the desired data string. Thus, the user executes the PEM part of the full actuation sequence for a data string to indicate the key used, after which the PT algorithm makes a new guess based on the additional new, but ambiguous, input. Then the user can decide to either continue making ambiguous inputs or specify one of the already ambiguously entered text characters. Specifying the multi-tap key used to enter a data string using the emulated keyboard has the same effect as pressing the key itself on the emulated keyboard: it enters the subset of data strings that are typed using that key (i.e., all the data strings in that key's tap order). By enabling the user to correct the first or latest data strings (or both) entered while typing a word, the user can reduce the solution space for the correct word.

It is the fact that two different actuator are used to enter an actuation sequence that makes it possible to use this guess correction method. Because the first part of the full actuation sequence to enter a specific text character is used to specify the emulated keyboard's key that types a particular data string is executed using one actuator (one in the group comprising the PEM which in the example is key 3511, 3512, 3513 or 3514) and second part of the actuation sequence specifies the position of that data string in the tap order of the specified key is executed using as separate actuator (one in the group comprising the SEM which in the examples is button 3515), the emulating keyboard's operating software (or that of the typable device of which it is a part) recognizes operation of the button 3515 as a correction. With existing PT algorithms on multi-tap keyboards such as phone keypads, indicating the key requires only actuating the key, and specifying a data string's place in the tap order of that key requires use of the same key, which is also used to enter new text characters. Thus, the operating software cannot tell whether an actuation of that key is a correction to an already entered data string or entry of a new data string. Most PT software requires a designated Next key for scrolling through possibilities for letters or words. However, this Next key has no part in entering text characters and therefore cannot function in the same way as the SEM key (button 3515) in the correction function just described.

The correction method for PT algorithms for emulating keyboards can be applied to existing word-by-word and letter-by-letter PT algorithms as follows. The key defined as the Next key is redefined as a Tap Order Key, and operates just like the button 3515 above. If the guess by a letter-by-letter PT algorithm is wrong, the user can correct it directly by using the Tap Order key to finish the actuation sequence for entering the correct text character (actuation sequences on 12-key phone keypads consist of actuating a key some number of times equal to the desired data string's position in the tap order of text characters assigned to that key). For example, if the user presses the 8 key to type a ‘v’ but the PT algorithm's guess is ‘t’, the user can press the Tap Order key three times to specify ‘v’. Then the user operates one of the twelve keys to enter the next text character.

If the PT algorithm is word-by-word, after noticing an incorrect guess, the user can operate the Tap Order key a number of times to indicate the position in the tap order of the particular text character being corrected. As described above, this can be the just entered text character, the first ambiguous text character in the word, or the first text character in the word being typed and then the just entered text character. In this modification to the guess correction operation of currently available PT algorithms, the two parameter input means normally executed using the same key are split, with one, the key choice-PIM (which here enters both the row-IP and column-IP), being entered using the appropriate key in the multi-tap keyboard, but the tap order-IP which is normally entered using the number-PIM of the same key is now entered using the number-PIM of a separate, defined Tap Order key. Following is one example of how the Tap Order Key can be used to correct an incorrect word guess of the PT algorithm. In this example, the user is using a keyboard setup where the first entry mechanism in the actuation sequence is used to specify which key of a phone keypad is used to enter an intended data string (e.g., the user only enters the input parameters which specify which key is used to enter the data string before the PT algorithm makes its guess). The user intends to enter the word ‘rat’ into the typable device, but the PT algorithm guesses the word wrong after the user finishes typing ‘rat’. In this example, the PT software is set up to correct the first remaining ambiguous text character, so when the user sees that the PT algorithm guess is wrong, he operates the Tap Order Key to complete the actuation sequence for the ‘r’, actuating it three times. Then if the PT algorithm's next guess is also wrong, the user finishes the actuation sequence for the ‘a’ by pressing the Tap Order Key once. Then if the PT algorithm's next guess is also wrong, the user operates the Tap Order Key to finish the actuation sequence for the ‘t’, pressing it once. If the PT software is set up to correct the last remaining ambiguous text character, the actuation sequences would be completed in opposite order, first ‘t’, then ‘a’, and last ‘r’. It is unlikely that the PT algorithm will continue to guess wrong since completing the entry of (i.e., definitively entering) each additional ambiguous data string provides more information to the PT algorithm and eliminates possibilities. For alternated keyboard setups, the Tap Order Key can be used to enter input parameters other than the tap order-IP to complete entry of an ambiguously entered data string. In fact, it can be used to complete the entry of any actuation sequence, no matter what input parameter is not entered when partially entering data strings while operating under PT software.

In one embodiment of electronic typable device 211, keypad 230 is replaced with 12-key phone keyboard 2100 and center button 205 is defined as the Tap Order key. Alternatively, center button 205 can be defined as the Next key and soft key 206 (or any other actuator in the control interface 213) can be defined as the Tap Order key. In one embodiment of electronic typable device 211, keypad 230 is replaced with 12-key phone keyboard 2100, interface control 213 is replaced by interface control 513, and center button 205 is defined as the Tap Order key. In either of these two embodiments, center button 205 can be defined as the Next key and soft key 206 (or any other actuator in the control interface 213 or 513) can be defined as the Tap Order key.

In another embodiment of electronic typable device 211, keypad 230 is replaced by 20 key keypad 921 comprising 20 keys 1901-1920 arranged in four horizontal rows of five keys each, and center button 205 is defined as the Tap Order key. In another embodiment of electronic typable device 211, keypad 230 is replaced by 20 key keypad 921 comprising 20 keys 1901-1920 arranged in four horizontal rows of five keys each, interface control 213 is replaced by interface control 513, and center button 205 is defined as the Tap Order key. In either of these two embodiments, center button 205 can be defined as the Next key and soft key 206 (or any other actuator in the control interface 213 or 513) can be defined as the Tap Order key.

The electronic device 211 can be a phone, PDA, handheld computer, GPS device, MP3 player, video player, digital camera, electronic game, entertainment device remote, radio, TV, DVD player, or any other type of electronic device incorporating a keyboard or any typable device.

The predictive text algorithms for the emulating keyboards and the modified predictive text algorithm described above are implemented in software which runs on a logic unit in the keyboard or in the typable device. The operating software for the typable device comprises instructions for the implementation and realization of these predictive text algorithms and the method for correcting incorrect guesses. In the modified PT algorithms just described for emulating keyboards, the other operating rules of the PT algorithm and software may be as described above for T9-like, iTap-like, TenGo-like and Letterwise-like PT algorithms and software. It will be obvious to one skilled in the art of predictive text algorithms how to modify those rules to work in conjunction with the guess correction rules just described using keyboard 3500 as an example.

The descriptions of operation of the keyboards disclosed here are relatively comprehensive, describing not only how to enter letters (the most important text characters for most text entry-related applications), but also how to enter numbers, punctuation and other text characters, and how to perform text-entry-related functions such as clear, shift (capitalization), scrolling through choices, and more. If the predictive text algorithms under which a disclosed keyboards is operating is simpler than or different from those described here, appropriate changes can be made to the operation of the disclosed keyboards. In some cases, fewer actuators will be needed for the entry of text characters using a disclosed keyboard under a predictive text algorithm. If only letters are to be entered, the keypad of the disclosed keyboard may be all that is required. Also, the drawings of some of the disclosed keyboards include extra actuators. These may be used in some embodiments and not others (for example, a disclosed keyboard operating under a Letterwise-type PT algorithm may require fewer actuators than one operating under a T9-type PT algorithm), and can be eliminated from actual implementations of the particular disclosed keyboard if not used. Some of the keyboards in the drawings are standard interfaces on some electronic devices already on the market, and one or more of the disclosed keyboards may be implemented using some subset of the total set of actuators comprising that interface. Also, some keyboards may have less functionality than those described (for example, some keyboards may not allow capitalization in which case the disclosed keyboard would have no use for a shifting or shift-locking capability, and those keyboards may comprise fewer actuators than disclosed keyboard embodiments with more functionality.

When an emulating keyboard is used to enter data strings under a predictive text algorithm, the first step is operate the parameter input means to enter the input means that identifies uniquely one of the keys of the emulated keyboard. Identifying that key identifies a subset of the data strings that the emulating keyboard can enter, those data strings that are entered using the identified key of the emulated keyboard. It is from among this subset of data strings that the PT algorithm must choose one as its guess. If the last PEM hold-PIM is used, as is the case in most embodiments disclosed above, the subset of data strings from among which the PT algorithm must choose a guess consists of all data strings entered using the identified key either with shift or without shift. Note when discussing predictive text algorithms, software incorporating them, and typable devices running on that software, the word ‘enter’ is sometimes used to refer to the act of actuating one of the text-entry keys of a multi-tap keyboard, or specifying one of the text-entry keys of a multi-tap of an emulated keyboard by operating at least one actuator of an emulating keyboard. In reality, pressing or specifying the text-entry key does not enter only one data string, it enters all data strings that are typed using that key, or rather the operating software comprising the predictive text software receives input from actuation of that key, or from actuation of at least one key of an emulating keyboard to specify that key, which it interprets as meaning that one of the text characters that can be entered using that key in multi-tap mode is the text character the user intends to enter. In PT mode, entering a text character simply means providing the operating software and PT algorithm with a subset of text characters from among which it must try to guess the one the user really intends to enter.

A number of emulating keyboards have been described above which emulate keyboards operating under a PT algorithm and which operate under a PT algorithm themselves. For purposes of illustration, several examples of the subsets of key data strings (lowercase letters only) input into the typable device or logic unit, or at least indicated to them, by identification of the specific key of the emulated keyboard are given immediately below.

A keyboard such as keyboard 1400 in FIG. 7 comprising four actuators, three of which operate in multitap mode to enter text characters, and one of which operates as a Next guess key to scroll through a list of guesses or prompt the PT algorithm to provide the next guess. The eight letter keys, keys 2 through 8, of the emulated 12-key phone keyboard when specified using keyboard 1400 indicate respectively that the intended letter is one of the letters in the following sets:

a. {abc}, {def}, {ghi}, {jkl}, {mno}, {pqrs}, {tuv}, and {wxyz}.

A keyboard such as keyboard 1300 in FIG. 18 comprising three actuators, two of which operate in multitap mode to enter text characters, one of which operates as a Next guess key to scroll through a list of guesses or prompt the PT algorithm to provide the next guess. When keyboard 1300 is operated to provide the row-IP and section-IP values (20-1 and 20-2 defined in FIG. 2) to the typable device, it indicates that the intended letter is one of the letters in the following sets associated with first row-left section, first row-right section, second row-left section, second row-right section, third row-left section, third row-right section respectively (the first row here refers to the first row of letter keys):

a. {qwert}, {yuiop}, {asdfg}, {hjkl}, {zxcvb}, {nm}.

A keyboard such as keyboard 1800 in FIG. 14 comprising six actuators, five of which operate in multitap mode to enter text characters, one of which operates as a Next guess key to scroll through a list of guesses or prompt the PT algorithm to provide the next guess. There are eleven sets of row-IP and section-IP values (20-1B and 20-2B respectively defined in FIG. 13) that can be provided to the typable device for entering letters which are the following and which are ordered by row (i.e., first row of letter keys-first section, second row of letter keys-first section . . . third row of letter keys-fourth section; there are no letters in the fifth section of the third row of keys):

a. {qw}, {er}, {ty}, {op}, {as}, {df}, {gh}, {jk}, {l}, {zx}, {cy}, {bn}, {m}.

Unless otherwise defined, all technical terms used herein have the same meaning as commonly understood by one of ordinary skill in the art to which this invention belongs. All publications, patent applications, patents, and other references mentioned herein are incorporated by reference in their entirety. In the case of conflict, the present specification, including definitions will control. In addition, the particular embodiments discussed above are illustrative only and not intended to be limiting.

The foregoing description of the invention has been presented describing certain operable and preferred embodiments. It is not intended that the invention should be so limited since variations and modifications thereof will be obvious to those skilled in the art, all of which are within the spirit and scope of the invention. Although the invention has been disclosed in terms of a number of preferred embodiment and variations thereon, it will be understood that numerous additional modifications and variations could be made thereto without departing from the scope of the invention as defined in the following section.

As used herein, the term “plurality” refers to two or more items or components. The terms “comprising,” “including,” “carrying,” “having,” “containing,” and “involving,” whether in the written description or the claims and the like, are open-ended terms, i.e., to mean “including but not limited to.” Thus, the use of such terms is meant to encompass the items listed thereafter, and equivalents thereof, as well as additional items. Only the transitional phrases “consisting of” and “consisting essentially of” are closed or semi-closed transitional phrases, respectively, with respect to the claims.

The inventions herein are not limited in their application to the details of construction and the arrangement of components set forth in the preceding description or illustrated in the drawings.

The inventions are capable of embodiments and of being practiced or of being carried out in various ways beyond those exemplarily presented herein.

Having now described some illustrative embodiments of the invention, it should be apparent to those skilled in the art that the foregoing is merely illustrative and not limiting, having been presented by way of example only. Numerous modifications and other embodiments are within the scope of one of ordinary skill in the art and are contemplated as falling within the scope of the invention. In particular, although many of the examples presented herein involve specific combinations of method acts or system elements, it should be understood that those acts and those elements may be combined in other ways to accomplish the same objectives.

Further, acts, elements, and features discussed only in connection with one embodiment are not intended to be excluded from a similar role in other embodiments.

It is to be appreciated that various alterations, modifications, and improvements can readily occur to those skilled in the art and that such alterations, modifications, and improvements are intended to be part of the disclosure and within the spirit and scope of the invention.

Moreover, it should also be appreciated that the invention is directed to each feature, system, subsystem, or technique described herein and any combination of two or more features, systems, subsystems, or techniques described herein and any combination of two or more features, systems, subsystems, and/or methods, if such features, systems, subsystems, and techniques are not mutually inconsistent, is considered to be within the scope of the invention as embodied in the claims.

Use of ordinal terms such as “first,” “second,” “third,” and the like in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Those skilled in the art should appreciate that the parameters and configurations described herein are exemplary and that actual parameters and/or configurations will depend on the specific application in which the systems and techniques of the invention are used.

Those skilled in the art should also recognize or be able to ascertain, using no more than routine experimentation, equivalents to the specific embodiments of the invention. It is therefore to be understood that the embodiments described herein are presented by way of example only and that, within the scope of the appended claims and equivalents thereto; the invention may be practiced otherwise than as specifically described.

1. A method of entering a set of data strings into a typable device, the method comprising:
providing a multi-tap keyboard comprising a plurality of keys;
a first step of selectively operating one of the keys in a first mutually exclusive set of said plurality of keys of said multi-tap keyboard to communicate to said typable device a value for at least two input parameters for a contiguous set of keys of a second keyboard;
a second step of selectively operating one of the keys in a second mutually exclusive set of said plurality of keys of said multi-tap keyboard to communicate to said typable device a value for at least one input parameter for said contiguous set of keys of said second keyboard;
evaluating the values for said input parameters for said contiguous set of keys of said second keyboard communicated to said typable device by selective operation of said keys of said multi-tap keyboard to determine the specific key in said contiguous set of keys of said second keyboard and the specific manner of operation of said specific key that is specified by said values for said input parameters;
entering into said typable device the data string that would be entered into a typable device comprising said second keyboard by operating said specific key of said second keyboard in said specific manner of operation;
wherein said set of data strings consists of all data strings enterable into a typable device using said contiguous set of keys of said second keyboard without employing a shift key.

2. The method of claim 1 wherein an additional input parameter is communicated to said typable device by selectively operating said one of said keys in said first mutually exclusive set of said plurality of keys of said multi-tap keyboard or said one of said keys in said second mutually exclusive set of said plurality of keys of said multi-tap keyboard; and
wherein said set of data strings additionally consists of all data strings enterable into a typable device using said contiguous set of keys of said second keyboard in conjunction with a shift key.

3. The method of claim 1 comprising the third step of selectively operating one of the keys in a third mutually exclusive set of said plurality of keys of said multi-tap keyboard to communicate to said typable device a value for at least one input parameter for a contiguous set of keys of a second keyboard; said third step being performed prior to evaluating the values for input parameters communicated to said typable device.

4. The method of claim 1 wherein the values of said at least two input parameters communicated to said typable device by selectively operating one of the keys in said first mutually exclusive set of said plurality of keys of said multi-tap keyboard uniquely specify one key in said set of contiguous keys of said second keyboard by specifying its physical location; and
wherein the values of said at least one input parameter communicated to said typable device by selectively operating one of the keys in said second mutually exclusive set of said plurality of keys of said multi-tap keyboard specifies how said one key in said set of contiguous keys of said second keyboard is operated to enter a specific data string.

5. The method of claim 3 wherein the value of one of said at least one input parameter communicated to said typable device by selectively operating one of the keys in said second mutually exclusive set of said plurality of keys of said multi-tap keyboard specifies a row of said second keyboard; and
wherein the value of said at least two input parameters communicated to said typable device by selectively operating one of the keys in said first mutually exclusive set of said plurality of keys of said multi-tap keyboard specifies any information in addition to said specified row necessary to uniquely identify a key in said set of contiguous keys of said second keyboard and additionally specifies how said uniquely identified key is operated to enter a data string.

6. The method of claim 1 wherein said second keyboard is a multi-tap keyboard and the value of one of said input parameters for said contiguous set of keys of said second keyboard specifies how many times said key in said contiguous set of keys of said second keyboard specified by other input parameters is operated to enter a specific data string.

7. The method of claim 1 wherein said second keyboard is a QWERTY keyboard; and
wherein the value of a first input parameter indicates the row of a key of said second keyboard operable to enter a specific data string, the value of a second input parameter indicates the section of said row of said second keyboard in which is located said key of said second keyboard operable to enter said specific data string, the value of a third input parameter indicates the ordinal position of said key in said section of said row of said second keyboard, and optionally the value of a fourth input parameter indicates whether said specific data string is capitalized or not when said specific data string is a letter.

8. The method of claim 1 wherein said second keyboard comprises a phone keypad; and
wherein the value of a first input parameter indicates the row of a key of said second keyboard operable to enter a specific data string, the value of a second input parameter indicates the column of said second keyboard in which is located said key of said second keyboard operable to enter said specific data string, the value of a third input parameter indicates the tap order of said specific data string on said key of said second keyboard operable to enter said specific data string, and optionally the value of a fourth input parameter indicates whether said specific data string is capitalized or not when said specific data string is a letter.

9. The method of claim 4 further comprising a tap order key; and
wherein said second keyboard is a phone keypad;
wherein said second step is eliminated;
wherein evaluating the values for said input parameters for said contiguous set of keys of said second keyboard communicated to said typable device by selective operation of said one of said keys in said first mutually exclusive set of said plurality of keys of said multi-tap keyboard is done by predictive text software which guesses from said values for said input parameters for said contiguous set of keys of said second keyboard which data string is intended to be entered; and
wherein said guessed data string is entered into said typable device; and
further comprising the optional step of operating said tap order key to enter a value of the input parameter specifying the tap order of the correct data string if the data string guessed by said predictive text software is incorrect.

10. The method of claim 5 further comprising a next key; and
wherein said second keyboard is a phone keypad;
wherein said second step is eliminated;
wherein evaluating the values for said input parameters for said contiguous set of keys of said second keyboard communicated to said typable device by selective operation of said one of said keys in said first mutually exclusive set of said plurality of keys of said multi-tap keyboard is done by predictive text software which guesses from said values which data string is intended to be entered; and
wherein said guessed data string is entered into said typable device; and
further comprising the optional step of operating said next key to scroll through a list of possible data strings and choose another data string if said guessed data string is incorrect.

11. A typable device comprising:
a multi-tap keyboard operable to enter a set of data strings into said typable device comprising:
a first mutually exclusive group of keys operable to communicate to said typable device values for a first set of at least two input parameters for a contiguous set of keys of a second keyboard;
a second mutually exclusive group of keys operable to communicate to said typable device values for a second set of at least one input parameter for said contiguous set of keys of a second keyboard; and
software instructions for evaluating the values entered for said first and second sets of input parameters and determining a data string to enter into said typable device;
wherein a key in said first mutually exclusive group of keys and a key in said second mutually exclusive group are operated in sequence to enter values for said input parameters; and
wherein said set of data strings consists of only those data strings enterable into a typable device using said contiguous set of keys of said second keyboard without employing a shift key.

12. The typable device of claim 11 wherein either said first mutually exclusive group of keys or said second mutually exclusive group of keys is operable to communicate to said typable device values for at least one additional input parameter for said contiguous set of keys of said second keyboard; and
wherein said set of data strings additionally consists of those data strings enterable into a typable device using said contiguous set of keys of said second keyboard in conjunction with a shift key.

13. The typable device of claim 11 wherein the value of a first input parameter in said first set of at least two input parameters is the ordinal value of the row in which one of said set of contiguous keys of said second keyboard is located and the value of a second input parameter in said first set of at least two input parameters is the ordinal value of the column or position in the row in which said one of said set of contiguous keys of said second keyboard is located.

14. The typable device of claim 11 wherein said first and said second sets of input parameters together contain four different members.

15. The keyboard of claim 11 further comprising a Next key, a Tap Order Key, or both a Next key and a Tap Order Key; and predictive text software instructions; and
wherein said predictive text software instructions evaluate the values of said first set of at least two input parameters and guess which of said set of data strings to enter into said typable device.

16. The keyboard of claim 15 comprising a Tap Order Key;
wherein said predictive text software instructions enable word-by-word predictive text functionality;
wherein said predictive text software instructions evaluate the values of said first set of at least two input parameters and guess which word to enter into said typable device; and
wherein said Tap Order Key is operable to complete the actuation sequence of the first remaining ambiguous data string in the current word guess of the predictive text software.

17. The keyboard of claim 11 wherein said first mutually exclusive group of keys consists of three keys;
wherein said second keyboard is a phone keypad;
wherein said first set of at least two input parameters comprises the column-IP, shift-IP and tap number-IP; and
wherein said column-IP is entered using key choice-PIM and said tap number-IP is entered using number-PIM.

18. The keyboard of claim 17 wherein said multi-tap keyboard comprises a four-way navigation device with a center key or a click wheel with a center key;
wherein the three keys in said first mutually exclusive group of keys are three of the four keys of said four-way navigation device or said click wheel;
wherein said second mutually exclusive group of keys consists solely of either the remaining key of said four-way navigation device or click wheel, or the center key; and
wherein the key not in said first or said second mutually exclusive sets of keys is operable to enter spaces into said typable device.

19. Operating software for a typable device comprising predictive text software instructions that enable said typable device to operate in predictive text mode;
wherein said typable device comprises a multi-tap keyboard comprising a plurality of keys, a first key of which is not used to enter data strings; and
wherein when said typable device is operating in predictive text mode, said first key is operable to enter the tap order of one of the text characters already partially entered into said typable device.

20. The operating software for a typable device of claim 19 wherein said first key is operable to enter the tap order of the first ambiguous text character in a currently selected word.
